(19) United States
(12) Patent Application Publication
(10) Pub. No.: US 2015/0151227 A1
(43) Pub. Date: Jun. 4, 2015

(54) FILTER DEVICE

(71) Applicant: TOKYO ELECTRON LIMITED, Minato-ku (JP)

(72) Inventors: Koji TAKAYANAGI, Koshi City (JP); Kousuke Yoshihara, Koshi City (JP)

(73) Assignee: TOKYO ELECTRON LIMITED, Minato-ku (JP)

(21) Appl. No.: 14/541,450

(22) Filed: Nov. 14, 2014

(30) Foreign Application Priority Data
Nov. 29, 2013 (JP) 2013-248396

(51) Int. Cl. B01D 35/34; H01L 21/67; B01D 35/02

(52) U.S. Cl. CPC B01D 35/34; B01D 35/02; H01L 21/67023

(57) ABSTRACT

A filter device includes a housing having space, a filter in the space of the housing, a first joint connected to a first port of the housing and having an open end which connects to a supply path of a processing liquid, a second joint connected to a second port of the housing and having an open end which connects to the path, and an exhaust joint connected to an exhaust port of the housing and having an open end which connects to an exhaust path. The first and second ports introduce or discharge the liquid and have openings to the opposite end portions of the space, respective, the filter is intersecting a straight line passing through the centers of the first and second ports, and the first, the second and exhaust joints are formed to extend in the same direction outside the space of the housing.

### CROSS-REFERENCE TO RELATED APPLICATIONS

The present application is based upon and claims the benefit of priority to Japanese Patent Application No. 2013-248396, filed Nov. 29, 2013, the entire contents of which are incorporated herein by reference.

### BACKGROUND OF THE INVENTION

1. Field of the Invention

The present invention relates to a filter device.

2. Description of Background Art

In a semiconductor manufacturing process, various processing liquids, such as a resist agent, a liquid developer or a rinse liquid, are supplied to a supply target such as a semiconductor wafer. When supplying a processing liquid, a filter device for removing foreign substances in the processing liquid is used. For example, International Publication No. 2009/069402 describes a filter device that includes a housing, a housing lid, a filter, an inlet for a processing liquid, an outlet for the processing liquid, and an exhaust vent.

The filter has a cylindrical shape that extends in an up-down direction, and is accommodated in the housing. All of the inlet, the outlet and the vent are provided on the housing lid and extend upward. A cylindrical side flow path is formed on an outer side of the filter, and an upper end part of the side flow path is connected to the vent. An inner side of the filter is partitioned into a center inner side flow path and a center outer side flow path. An upper end part of the center inner side flow path is connected to the inlet, and an upper end part of the center outer side flow path is connected to the outlet. At a lower end part of the filter, a bottom flow path is formed that extends along a bottom surface of the accommodating space. A center part of the bottom flow path is connected to the center inner side flow path, and a peripheral edge part of the bottom flow path is connected to the side flow path over an entire circumference.

The processing liquid that has flowed into the inlet passes through the center inner side flow path to descend, passes through the bottom flow path to flow into the lower end part of the side flow path, passes through the filter while ascending to flow into the center outer side flow path, and flows out from the outlet. A gas separated from the processing liquid gathers at an upper portion of the side flow path and is exhausted from the vent. According such a filter device, by causing the processing liquid to pass through the filter, foreign substances in the processing liquid are removed. The entire contents of this publication are incorporated herein by reference.

### SUMMARY OF THE INVENTION

According to one aspect of the present invention, a filter device includes a housing having an accommodating space, a filter accommodated in the accommodating space of the housing, a first tubular joint connected to a first liquid feeding port of the housing and having an open end which connects to a supply path of a processing liquid for a semiconductor manufacturing process, a second tubular joint connected to a second liquid feeding port of the housing and having an open end which connects to the supply path of the processing liquid, and a tubular exhaust joint connected to an exhaust port of the housing and having an open end which connects to an exhaust path. The first and the second liquid feeding ports introduces or discharges the processing liquid and positioned such that the first and the second liquid feeding ports have openings to the opposite end portions of the accommodating space, respectively, the exhaust port exhausts gas separated from the processing liquid and positioned such that the exhaust port has an opening to the accommodating space, the filter is accommodated in the accommodating space such that the filter is intersecting a straight line passing through the center of the first liquid feeding port and the center of the second liquid feeding port, and the first tubular joint, the second tubular joint and the tubular exhaust joint are formed to extend in the same direction outside the accommodating space of the housing.

According to another aspect of the present invention, a filter device includes a housing having an accommodating space, and multiple filter components positioned adjacent to each other in a horizontal direction in the housing. Each of the filter components includes a filter accommodated in the accommodating space of the housing, a first tubular joint connected to a first liquid feeding port of the housing and having an open end which connects to a supply path of a processing liquid for a semiconductor manufacturing process, a second tubular joint connected to a second liquid feeding port of the housing and having an open end which connects to the supply path of the processing liquid, and a tubular exhaust joint connected to an exhaust port of the housing and having an open end which connects to an exhaust path, the first and the second liquid feeding ports introduces or discharges the processing liquid and positioned such that the first and the second liquid feeding ports have openings to the opposite end portions of the accommodating space, respectively, the exhaust port exhausts gas separated from the processing liquid and positioned such that the exhaust port has an opening to the accommodating space, the filter is accommodated in the accommodating space such that the filter is intersecting a straight line passing through the center of the first liquid feeding port and the center of the second liquid feeding port, the first tubular joint and tubular exhaust joint of each of the filter components are extending out and upward with respect to the accommodating space of the housing, and the second tubular joint of each of the filter components is connected with each other.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 illustrates a perspective view of a coating and developing apparatus according to a first embodiment;

FIG. 2 illustrates a cross-sectional view along an II-II line in FIG. 1;

FIG. 3 illustrates a cross-sectional view along an line in FIG. 2;

FIGS. 4A and 4B illustrate cross-sectional views of a filter device according to the first embodiment;

FIG. 5 illustrates a cross-sectional view illustrating a modified embodiment of the filter device according to the first embodiment;

FIG. 6 illustrates a cross-sectional view illustrating another modified embodiment of the filter device according to the first embodiment;

FIG. 7 illustrates a cross-sectional view illustrating another modified embodiment of the filter device according to the first embodiment;

FIG. 8 illustrates a cross-sectional view illustrating another modified embodiment of the filter device according to the first embodiment;

FIG. 9 illustrates a cross-sectional view illustrating a reference example of the filter device according to the first embodiment;

FIG. 10 illustrates a cross-sectional view illustrating another reference example of the filter device according to the first embodiment;

FIGS. 11A and 11B illustrate cross-sectional views illustrating a filter device according to a second embodiment;

FIG. 12 illustrates a cross-sectional view illustrating a modified embodiment of the filter device according to the second embodiment;

FIG. 13 illustrates a cross-sectional view illustrating another modified embodiment of the filter device according to the second embodiment;

FIG. 14 illustrates a cross-sectional view illustrating another modified embodiment of the filter device according to the second embodiment;

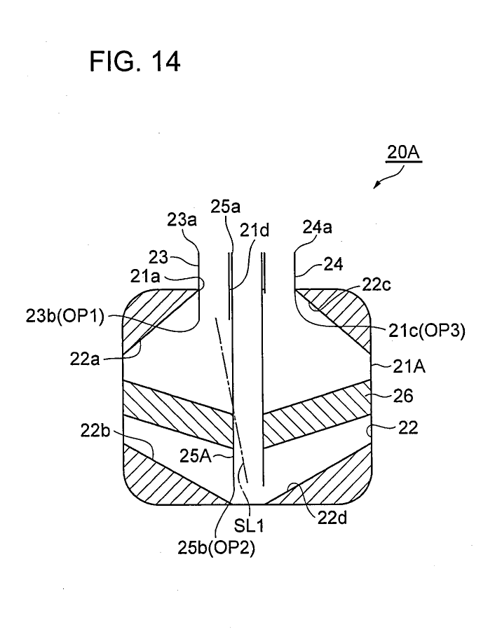

FIG. 15 illustrates a cross-sectional view illustrating another modified embodiment of the filter device according to the second embodiment;

FIG. 16 illustrates a cross-sectional view illustrating a filter device according to a third embodiment;

FIG. 17 illustrates a cross-sectional view illustrating a modified embodiment of the filter device according to the third embodiment;

FIG. 18 illustrates a cross-sectional view illustrating another modified embodiment of the filter device according to the third embodiment;

FIG. 19 illustrates a cross-sectional view of a filter device according to a fourth embodiment;

FIG. 20 illustrates a cross-sectional view illustrating a modified embodiment of the filter device according to the fourth embodiment;

FIG. 21 illustrates a cross-sectional view illustrating a reference example of the filter device according to the fourth embodiment;

FIG. 22 illustrates a cross-sectional view illustrating another reference example of the filter device according to the fourth embodiment; and

FIG. 23 illustrates a cross-sectional view illustrating another reference example of the filter device according to the fourth embodiment.

### DETAILED DESCRIPTION OF THE EMBODIMENTS

The embodiments will now be described with reference to the accompanying drawings, wherein like reference numerals designate corresponding or identical elements throughout the various drawings.

### First Embodiment

### Coating and Developing Apparatus

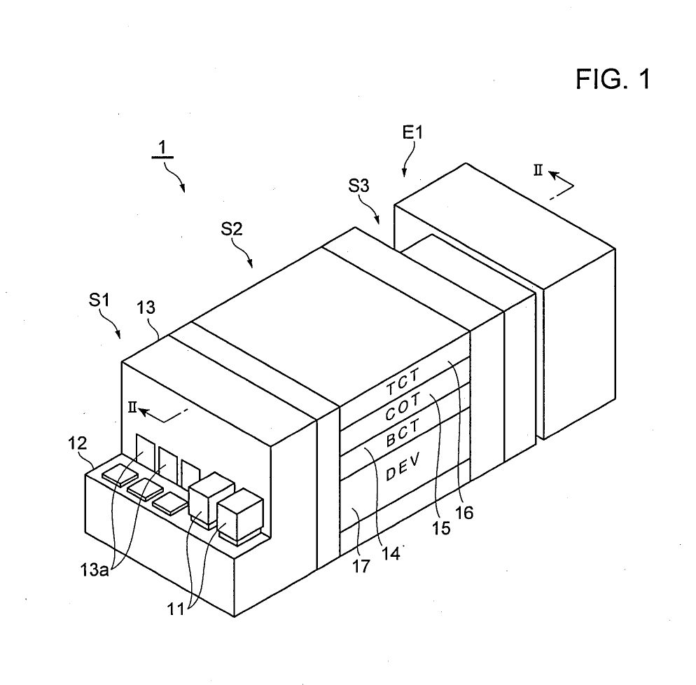

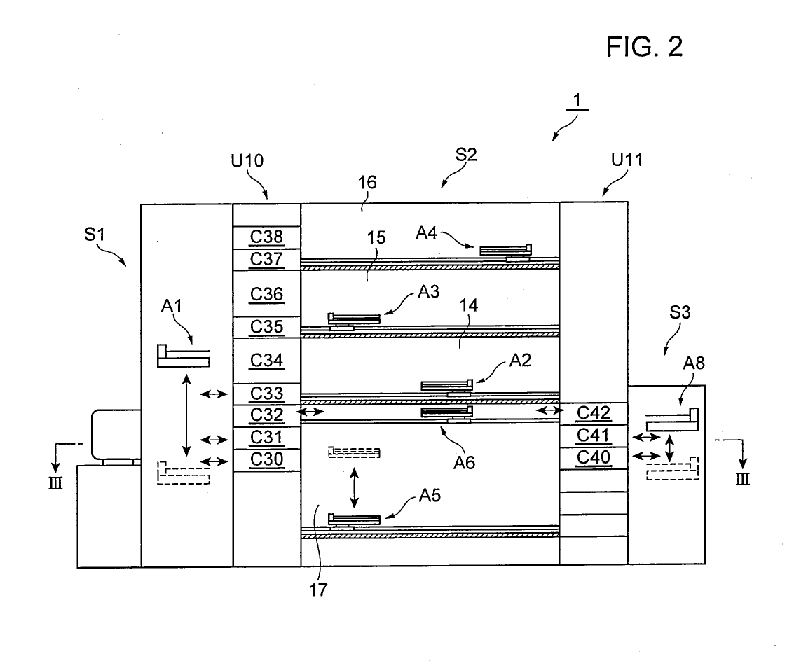

A coating and developing apparatus 1 performs processing in which a resist agent is applied to a surface of a wafer (substrate) to form a resist film before exposure processing is performed by an exposure apparatus (E1), and performs development processing of the resist film after the exposure processing is performed by the exposure apparatus (E1). As illustrated in FIGS. 1 and 2, the coating and developing apparatus 1 includes a carrier block (S1), a processing block (S2) that is adjacent to the carrier block (S1), and an interface block (S3) that is adjacent to the processing block (S2). In the following, “front,” “rear,” “left” and “right” in description of the coating and developing apparatus 1 refer to directions that are defined in such a manner that the interface block (S3) side is a front side and the carrier block (S1) side is rear side.

The carrier block (S1) has a carrier station 12 and a carry-in and carry-out part 13. The carrier station 12 supports multiple carriers 11. The carrier 11 accommodates multiple wafers (W) in a sealed state and has an open-close door (not illustrated in the drawings) on one side surface (11a) side for taking in and out the wafers (W). The carrier 11 is detachably installed on the carrier station 12 in such a manner that the side surface (11a) faces the carry-in and carry-out part 13 side.

The carry-in and carry-out part 13 has multiple open-close doors (13a) that respectively correspond to the plurality of the carriers 11 on the carrier station 12. By opening the open-close door on the side surface (11a) and the open-close door (13a) at the same time, interior of the carrier 11 and interior of the carry-in and carry-out part 13 are communicated with each other. The carry-in and carry-out part 13 has therein a transfer arm (A1). The transfer arm (A1) takes out the wafer (W) from the carrier 11 and passes the wafer (W) to the processing block (S2); and receives the wafer (W) from the processing block (S2) and returns the wafer (W) to the carrier 11.

The processing block (S2) has a bottom anti-reflection film formation (BCT) block 14, a resist film formation (COT) block 15, a top anti-reflection film formation (TCT) block 16 and a development processing (DEV) block 17. These blocks are stacked from a floor side in an order of the DEV block 17, the BCT block 14, the COT block 15 and the TCT block 16.

The BCT block 14 has therein a coating unit (not illustrated in the drawings), a heating and cooling unit (not illustrated in the drawings), and a carrying arm (A2) that carries the wafer (W) to these units. The coating unit applies a chemical solution for anti-reflection film formation to a surface of the wafer (W). The heating and cooling unit subjects the wafer (W) to a heat treatment in which, for example, the wafer (W) is heated by a hot plate to cure the chemical solution and the wafer (W) after heating is cooled by a cooling plate.

The COT block 15 has therein a coating unit (not illustrated in the drawings), a heating and cooling unit (not illustrated in the drawings), and a carrying arm (A3) that carries the wafer (W) to these units. The coating unit applies a chemical solution (resist agent) for resist film formation on a bottom anti-reflection film. The heating and cooling unit subjects the wafer (W) to a heat treatment in which, for example, the wafer (W) is heated by a hot plate to cure the resist agent and the wafer (W) after heating is cooled by a cooling plate. The resist agent may be of a positive type or a negative type.

The TCT block 16 has therein a coating unit (not illustrated in the drawings), a heating and cooling unit (not illustrated in the drawings), and a carrying arm (A4) that carries the wafer (W) to these units. The coating unit applies a chemical solution for anti-reflection film formation on a resist film. The heating and cooling unit subjects the wafer (W) to a heat treatment in which, for example, the wafer (W) is heated by a hot plate to cure the chemical solution and the wafer (W) after heating is cooled by a cooling plate.

DEV block 17 has therein multiple development processing units (substrate liquid processing devices) (U1), multiple heating and cooling units (heat treatment parts) (U2), a carrying arm (A5) that carries the wafer (W) to these units, and a direct carrying arm (A6) that carries the wafer (W) between front and rear sides of the processing block (S2) without going through these units.

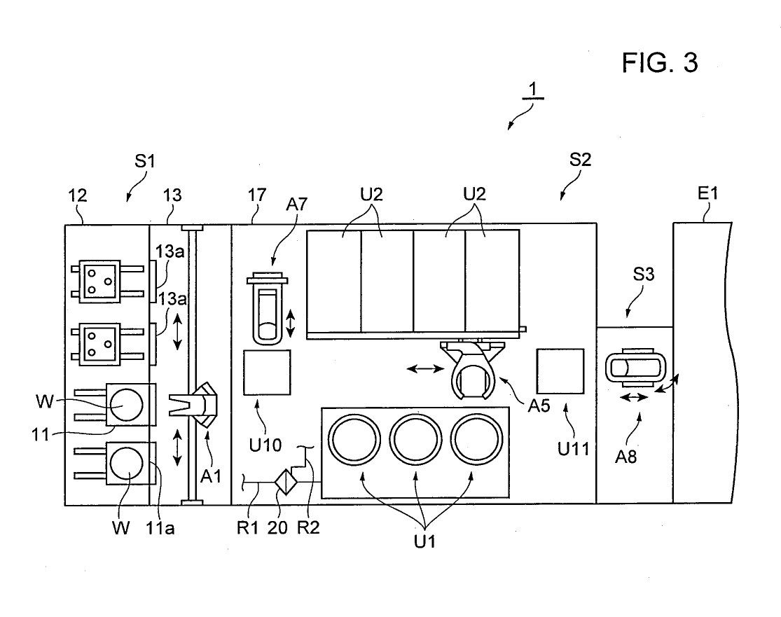

As illustrated in FIG. 3, the development processing unit (U1) performs development processing by supplying a liquid developer and a rinse liquid to a resist film that has been subjected to exposure processing. The heating and cooling unit (U2) performs heat treatments such as post exposure bake (PEB) and post baking (PB). The PEB is a process in which a resist film is heated before being subjected to development processing. The PB is a process in which a resist film is heated after being subjected to development processing. In these heat treatments, the heating and cooling unit (U2) heats the resist film by heating the wafer (W) using a hot plate, and cools, using a cooling plate, the wafer (W) that has been heated.

A shelf unit (U10) is provided on the rear side of the processing block (S2). The shelf unit (U10) is provided extending from the floor to the TCT block 16 and is partitioned into multiple cells (C30-C38) that are positioned in an up-down direction. A lifting arm (A7) is provided in a vicinity of to the shelf unit (U10). The lifting arm (A7) carries the wafer (W) between the cells (C30-C38). A shelf unit (U11) is provided on the front side of the processing block (S2). The shelf unit (U11) is provided extending from the floor to an upper portion of the DEV block 17 and is partitioned into multiple cells (C40-C42) that are positioned in the up-down direction.

The interface block (S3) is connected to the exposure apparatus (E1). The interface block (S3) has therein a transfer arm (A8). The transfer arm (A8) passes the wafer (W) from the shelf unit (U11) of the processing block (S2) to the exposure apparatus (E1), and receives the wafer (W) from the exposure apparatus (E1) and returns the wafer (W) to the shelf unit (U11).

In such a coating and developing apparatus 1, first, the carrier 11 is installed on the carrier station 12. In this case, the one side surface (11a) of the carrier 11 is directed toward the open-close door (13a) of the carry-in and carry-out part 13. Next, the open-close door of the carrier 11 and the open-close door (13a) of the carry-in and carry-out part 13 are both opened; the wafers (W) in the carrier 11 are taken out by the transfer arm (A1) and are sequentially carried to one of the cells of the shelf unit (U10) of the processing block (S2).

The wafers (W) that are carried by the transfer arm (A1) to the one of the cells of the shelf unit (U10) are sequentially carried by the lifting arm (A7) to the cell (C33) that corresponds to the BCT block 14. The wafers (W) that are carried to the cell (C33) are carried by the carrying arm (A2) to the respective units in the BCT block 14, and a bottom anti-reflection film is formed on a surface of each of the wafers (W).

The wafers (W) for each of which the bottom anti-reflection film is formed are carried by the carrying arm (A2) to the cell (C34) above the cell (C33). The wafers (W) that are carried to the cell (C34) are carried by the lifting arm (A7) to the cell (C35) that corresponds to the COT block 15. The wafers (W) that are carried to the cell (C35) are carried by the carrying arm (A3) to the respective units in the COT block 15, and a resist film is formed on the bottom anti-reflection film of each of the wafers (W).

The wafers (W) for each of which the resist film is formed are carried by the carrying arm (A3) to the cell (C36) above the cell (C35). The wafers (W) that are carried to the cell (C36) are carried by the lifting arm (A7) to the cell (C37) that corresponds to the TCT block 16. The wafers (W) that are carried to the cell (C37) are carried by the carrying arm (A4) to the respective units in the TCT block 16, and a top anti-reflection film is formed on the resist film of each of the wafers (W).

The wafers (W) for each of which the top anti-reflection film is formed are carried by the carrying arm (A4) to the cell (C38) above the cell (C37). The wafers (W) that are carried to the cell (C38) are carried by the lifting arm (A7) to the cell (C32) that corresponds to the direct carrying arm (A6), and are carried by the direct carrying arm (A6) to the cell (C42) of the shelf unit (U11). The wafers (W) that are carried to the cell (C42) are passed by the transfer arm (A8) of the interface block (S3) to the exposure apparatus (E1), and the resist film is subjected to exposure processing in the exposure apparatus (E1). The wafers (W) after being subjected to the exposure processing are carried by the transfer arm (A8) to the cells (C40, C41) below the cell (C42).

The wafers (W) that are carried to the cells (C40, C41) are carried by the carrying arm (A5) to the respective units in the DEV block 17 and are subjected to development processing. As a result, a resist pattern is formed on the surface of the wafer (W). The wafers (W) on each of which a resist pattern has been formed are carried by the carrying arm (A5) to the cells (C30, C31) of the shelf unit (U10) that correspond to the DEV block 17. The wafers (W) that are carried to the cells (C30, C31) are carried by the lifting arm (A7) to cells that can be accessed by the transfer arm (A1), and are returned by the transfer arm (A1) to the carrier 11.

The configuration of the coating and developing apparatus 1 is merely an example. A coating and developing apparatus may be one that includes liquid processing units such as a coating unit and a development processing unit, a pre-processing and post-processing unit such a heating and cooling unit, and a carrying device, and the number, type, layout and the like of these units may be suitably changed.

### Filter Device

The coating and developing apparatus 1 has liquid processing units such as the coating unit and the development processing unit. These liquid processing units respectively supply processing liquids, such as a chemical solution for anti-reflection film formation, a resist agent, a liquid developer or a rinse liquid, to the wafer (W) (supply target). As illustrated in FIG. 3, a filter device 20 is positioned in a supply path (R1) for supplying a processing liquid to each of the liquid processing units (see FIG. 3).

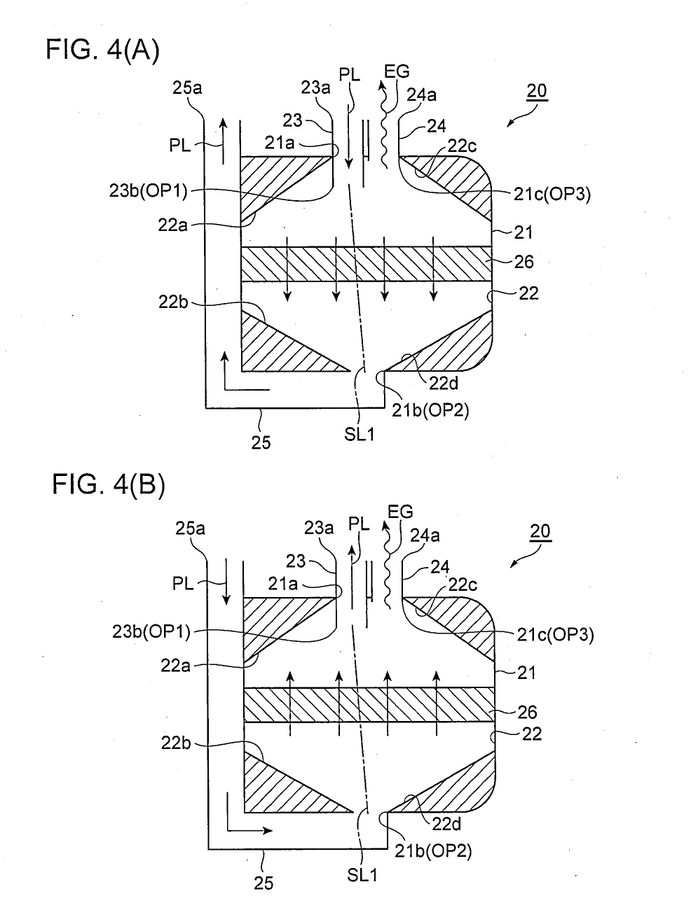

As illustrated in FIG. 4A and 4B, the filter device 20 includes a housing 21, a first liquid feeding joint 23, an exhaust joint 24, a second liquid feeding joint 25 and a filter 26.

The housing 21 is a container that has therein an accommodating space 22. That is, the filter device 20 further includes the accommodating space 22. At a center of an upper end part of the housing 21, openings (21a, 21c) are provided. At a center of a lower end part of the housing 21, an opening (21b) is provided.

The first liquid feeding joint 23 has a tubular shape and protrudes upward and downward from a peripheral edge part of the opening (21a). A lower end (23b) of the first liquid feeding joint 23 is positioned at an upper end part (22c) in the accommodating space 22 and forms a first liquid feeding port (OP1). The first liquid feeding port (OP1) opens to the upper end part (22c) in the accommodating space 22, and introduces or leads out a processing liquid (PL). The upper end part (22c) includes an upper end and its vicinity. An upper end (23a) of the first liquid feeding joint 23 is an open end that is open upward, and can be detachably connected to the supply path (R1) (see FIG. 3) of the processing liquid. That is, the first liquid feeding joint 23 has the open end (23a) that can be connected to the supply path (R1), is connected to the first liquid feeding port (OP1), and extends upward outside the accommodating space 22.

The exhaust joint 24 has a tubular shape and protrudes upward from a peripheral edge part of the opening (21c). The opening (21c) forms an exhaust port (OP3). The exhaust port (OP3) opens to the upper end part (22c) in the accommodating space 22, and exhausts a gas (EG) separated from the processing liquid (PL). The exhaust port (OP3) is positioned above the first liquid feeding port (OP1). An upper end (24a) of the exhaust joint 24 is an open end that is open upward, and can be detachably connected an exhaust path (R2) (see FIG. 3). That is, the exhaust joint 24 has the open end (24a) that can be connected to the exhaust path (R2), is connected to the exhaust port (OP3), and extends upward outside the accommodating space 22. The open end (24a) is positioned at the same height as the open end (23a).

The second liquid feeding joint 25 has a tubular shape. One end part of the second liquid feeding joint 25 is connected from below to the center of the lower end part of the housing 21. The one end part of the second liquid feeding joint 25 opens upward and is fixed to a peripheral edge part of the opening (21b). The opening (21b) forms a second liquid feeding port (OP2). The second liquid feeding port (OP2) opens to a lower end part (22d) in the accommodating space 22, and introduces or leads out the processing liquid (PL). The lower end part (22d) includes a lower end and its vicinity.

The second liquid feeding joint 25 extends along a peripheral edge side of the housing 21 and bends upward along the way. The bent part of the second liquid feeding joint 25 is positioned on an outer side than the peripheral edge of the accommodating space 22 in a plan view, and a portion that extends upward from the bent part passes around the accommodating space 22 and extends upward outside the accommodating space 22. An upper end (25a) of the second liquid feeding joint 25 is an open end that is open upward. That is, the second liquid feeding joint 25 has the open end (25a) that can be connected to the supply path (R1), is connected to the second liquid feeding port (OP2), and extends upward outside the accommodating space 22. The open end (25a) is positioned at the same height as the open end (23a) and the open end (24a).

As described above, the first liquid feeding joint 23, the second liquid feeding joint 25 and the exhaust joint 24 extend in the same direction outside the accommodating space 22. The housing 21, the first liquid feeding joint 23, the second liquid feeding joint 25 and the exhaust joint 24 are formed of, for example, a resin material.

The filter 26 is a sheet-like member that is formed of, for example, a non-woven fabric and is accommodated in the accommodating space 22 in a state of being orthogonal to a vertical direction. The filter 26 intersects a straight line (SL1) that passes through a center of the first liquid feeding port (OP1) and a center of the second liquid feeding port (OP2). A peripheral edge part of the filter 26 is fixed on an inner surface of the accommodating space 22.

An inner surface (22a) of the accommodating space 22 on the first liquid feeding port (OP1) side is formed in such a manner that the inner surface (22a) becomes closer to the filter 26 with increasing distance from the first liquid feeding port (OP1). As an example, the inner surface (22a) forms a cone-like shape that gradually widens as it extends downward.

An inner surface (22b) of the accommodating space 22 on the second liquid feeding port (OP2) side is formed in such a manner that the inner surface (22b) becomes closer to the filter 26 with increasing distance from the second liquid feeding port (OP2). As an example, the inner surface (22b) forms a cone-like shape that gradually widens as it extends upward.

The filter device 20 that is structured as described above is used by connecting one of the open ends (23a, 25a) to an upstream side of the supply path of the processing liquid, connecting the other one of the open ends (23a, 25a) to a downstream side of the supply path of the processing liquid, and connecting the open end (24a) to the exhaust path.

FIG. 4A illustrates flow of the processing liquid (PL) in the case where the open end (23a) is connected to the upstream side of the supply path of the processing liquid and the open end (25a) is connected to the downstream side of the supply path of the processing liquid. In this case, the processing liquid (PL) flows in from the first liquid feeding port (OP1) to the accommodating space 22, descends to pass through the filter 26, and flows out from the second liquid feeding port (OP2) to the outside of the accommodating space 22. Foreign substances in the processing liquid (PL) are removed by the filter 26. On an upper side of the filter 26, the gas (EG) separated from the processing liquid (PL) emerges. Since the first liquid feeding port (OP1) is positioned below the exhaust port (OP3), the gas (EG) gathers around the first liquid feeding joint 23 and is exhausted from the exhaust port (OP3).

FIG. 4B illustrates flow of the processing liquid (PL) in the case where the open end (25a) is connected to the upstream side of the supply path of the processing liquid and the open end (23a) is connected to the downstream side of the supply path of the processing liquid. In this case, the processing liquid (PL) flows in from the second liquid feeding port (OP2) to the accommodating space 22, ascends to pass through the filter 26, and flows out from the first liquid feeding port (OP1) to the outside of the accommodating space 22. Foreign substances in the processing liquid (PL) are removed by the filter 26. On the upper side of the filter 26, the gas (EG) separated from the processing liquid (PL) emerges to gather around the first liquid feeding joint 23 and is exhausted from the exhaust port (OP3).

In the filter device 20 described above, the first liquid feeding port (OP1) and the second liquid feeding port (OP2) are formed on opposite sides of each other, and the filter 26 intersects the straight line (SL1) that passes through the center of the first liquid feeding port (OP1) and the center of the second liquid feeding port (OP2). That is, the first liquid feeding port (OP1), the filter 26 and the second liquid feeding port (OP2) are positioned along a straight line. As a result, the flow of the processing liquid (PL) that flows into the accommodating space 22, passes through the filter 26 and flows out to the outside of the accommodating space 22 is simplified. Therefore, retention of the processing liquid (PL) in the accommodating space 22 can be suppressed. The first liquid feeding joint 23, the second liquid feeding joint 25 and the exhaust joint 24 are respectively connected to the first liquid feeding port (OP1), the second liquid feeding port (OP2) and the exhaust port (OP3), and these joints extend in the same direction outside the accommodating space 22. Therefore, even when the first liquid feeding port (OP1) and the second liquid feeding port (OP2) are formed on opposite sides of each other, the filter device 20 can be easily attached to and detached from the supply path (R1) of the processing liquid and the exhaust path (R2).

The first liquid feeding port (OP1) and the exhaust port (OP3) open to the upper end part (22c) in the accommodating space 22. Therefore, the first liquid feeding joint 23 and the exhaust joint 24, which extend upward, can be formed in simple linear shapes.

When the processing liquid (PL) is caused to flow in from the first liquid feeding port (OP1) and flow out from the second liquid feeding port (OP2), the exhaust port (OP3) is positioned on an upstream side of the filter 26. Therefore, the gas (EG) separated from the processing liquid (PL) can be exhausted on the upstream side of the filter 26.

When the processing liquid (PL) is caused to flow in from the second liquid feeding port (OP2) and flow out from the first liquid feeding port (OP1), the exhaust port (OP3) is positioned on a downstream side of the filter 26. Therefore, the gas (EG) separated from the processing liquid (PL) can be exhausted on the downstream side of the filter 26. In a case where a pump for pumping the processing liquid (PL) is positioned on a downstream side of the filter device 20, a negative pressure is likely to act on the processing liquid (PL) on the downstream side of the filter 26. Therefore, separation of the gas (EG) from the processing liquid (PL) is likely to occur on the downstream side of the filter 26. Therefore, that the gas (EG) can be exhausted on the downstream side is particularly beneficial in the case where the pump is positioned on the downstream side of the filter device 20.

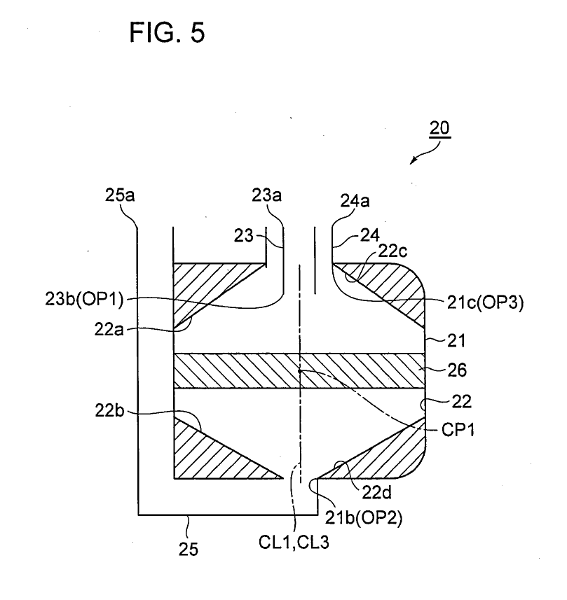

The exhaust joint 24 may be positioned in a manner surrounding the first liquid feeding joint 23, and, in association with this, the exhaust port (OP3) may have an annular shape that surrounds the first liquid feeding joint 23 (see FIG. 5). In this case, a center axis line (CL1) of the first liquid feeding joint 23 and a center axis line (CL3) of the exhaust joint 24 can both coincide with a center (CP1) of the filter 26. By making the center axis line (CL1) of the first liquid feeding joint 23 coincide with the center (CP1), variation in flow rates of the processing liquid (PL) corresponding to different portions of the filter 26 is suppressed. Therefore, the retention of the processing liquid (PL) can be further suppressed. By making the center axis line (CL3) of the exhaust joint 24 coincide with the center (CP1), the gas (EG) separated from the processing liquid (PL) can be efficiently collected and exhausted.

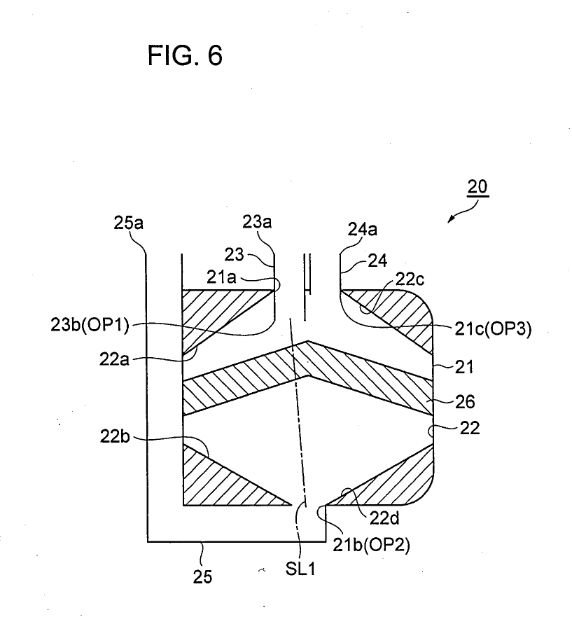

The filter 26 may also have a cone shape with a center part raised toward the first liquid feeding port (OP1) (see FIG. 6). In the case where the processing liquid (PL) flows from the first liquid feeding port (OP1) to the second liquid feeding port (OP2), the center part of the filter 26 is raised toward the liquid feeding port from which the processing liquid (PL) is introduced.

In the case where the processing liquid (PL) flows from the second liquid feeding port (OP2) to the first liquid feeding port (OP1), the center part of the filter 26 is raised toward the liquid feeding port from which the processing liquid (PL) is led out.

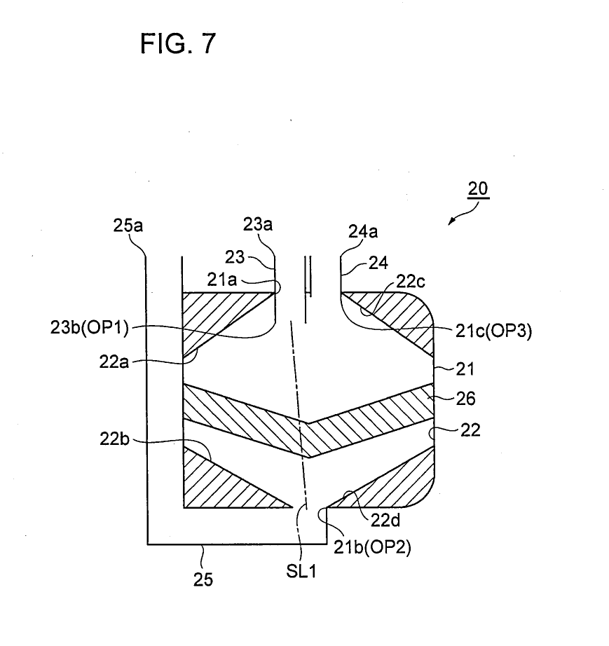

The filter 26 may also have a cone shape with a center part raised toward the second liquid feeding port (OP2) (see FIG. 7). In the case where the processing liquid (PL) flows from the first liquid feeding port (OP1) to the second liquid feeding port (OP2), the center part of the filter 26 is raised toward the liquid feeding port from which the processing liquid (PL) is led out. In the case where the processing liquid (PL) flows from the second liquid feeding port (OP2) to the first liquid feeding port (OP1), the center part of the filter 26 is raised toward the liquid feeding port from which the processing liquid (PL) is introduced. A difference between the flow rate of the processing liquid (PL) at the center part of the filter 26 and the flow rate of the processing liquid (PL) at the peripheral edge part of the filter 26 can be adjusted and the retention of the processing liquid (PL) can be further suppressed.

By allowing the filter 26 to have a shape of FIG. 6 or FIG. 7, the difference between the flow rate of the processing liquid (PL) at the center part of the filter 26 and the flow rate of the processing liquid (PL) at the peripheral edge part of the filter 26 can be adjusted and the retention of the processing liquid (PL) can be further suppressed.

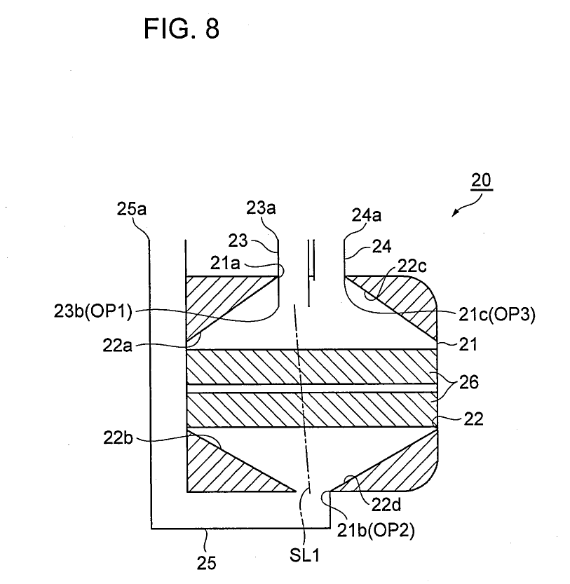

It is also possible to stack and position multiple the filters 26 in the accommodating space 22 (see FIG. 8). In this case, foreign substances in the processing liquid (PL) can be more reliably removed.

An inner surface (22a) of the accommodating space 22 on the first liquid feeding port (OP1) side is formed in such a manner that the inner surface (22a) becomes closer to the filter 26 with increasing distance from the first liquid feeding port (OP1). An inner surface (22b) of the accommodating space 22 on the second liquid feeding port (OP2) side is formed in such a manner that the inner surface (22b) becomes closer to the filter 26 with increasing distance from the second liquid feeding port (OP2). As a result, it becomes easy for the processing liquid (PL) to flow along the inner surface of the accommodating space 22. Therefore, the retention of the processing liquid (PL) can be further suppressed.

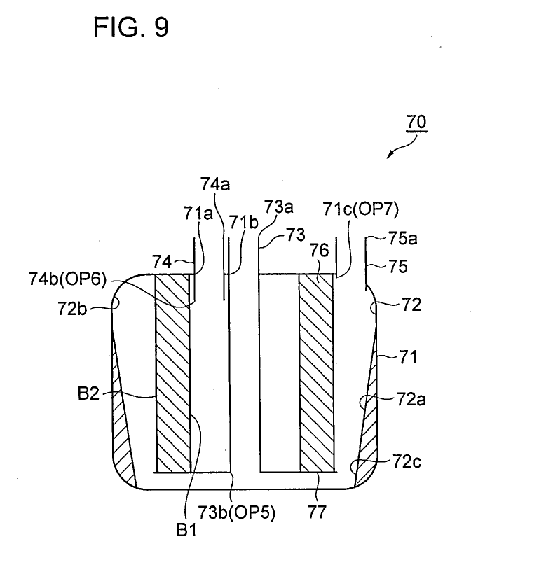

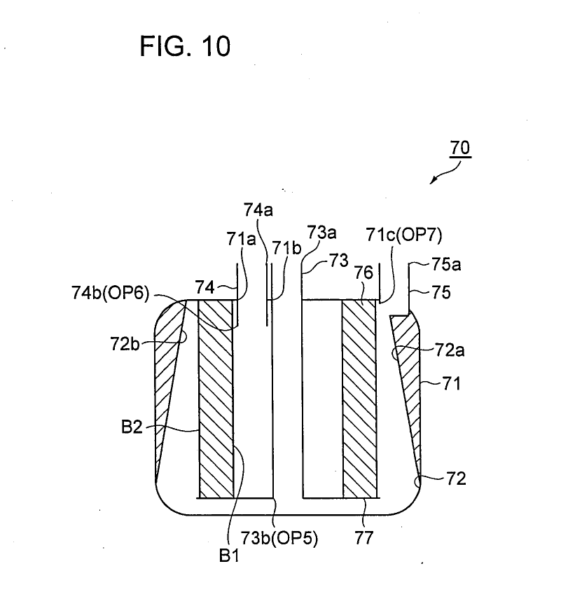

Making it easy for the processing liquid to flow along the inner surface of the accommodating space by adjusting the shape of the inner surface of the accommodating space can also be applied to filter devices of other embodiments. In the following, with reference to FIGS. 9 and 10, application examples are described.

A filter device 70 illustrated in FIG. 9 includes a housing 71, a first liquid feeding joint 73, a second liquid feeding joint 74, an exhaust joint 75, a filter 76 and a partition plate 77.

The housing 71 is a container that has therein an accommodating space 72. That is, the filter device 70 further includes the accommodating space 72. At a center of an upper end part of the housing 71, openings (71a, 71b) are provided. On a peripheral edge side of an upper end part of the housing 71, an opening (71c) is provided.

The first liquid feeding joint 73 has a tubular shape and protrudes upward and downward from a peripheral edge part of the opening (71b). A lower end (73b) of the first liquid feeding joint 73 is positioned at a lower end part (72c) in the accommodating space 72 and forms a first liquid feeding port (OP5). The first liquid feeding port (OP5) opens to the lower end part (72c) in the accommodating space 72, and introduces or leads out the processing liquid. The lower end part (72c) includes a lower end and its vicinity. An upper end (73a) of the first liquid feeding joint 73 is an open end that is open upward, and can be detachably connected to the supply path of the processing liquid. That is, the first liquid feeding joint 73 has the open end (73a) that can be connected to the supply path, is connected to the first liquid feeding port (OP5), and extends upward outside the accommodating space 72.

The second liquid feeding joint 74 has a tubular shape and protrudes upward and downward from a peripheral edge part of the opening (71a). A lower end (74b) of the second liquid feeding joint 74 is positioned at an upper end part (72b) in the accommodating space 72 and forms a second liquid feeding port (OP6). The second liquid feeding port (OP6) opens to the upper end part (72b) in the accommodating space 72, and introduces or leads out the processing liquid. The upper end part (72b) includes an upper end and its vicinity. An upper end (74a) of the second liquid feeding joint 74 is an open end that is open upward, and can be detachably connected to the supply path of the processing liquid. That is, the second liquid feeding joint 74 has the open end (74a) that can be connected to the supply path, is connected to the second liquid feeding port (OP6), and extends upward outside the accommodating space 72. The open end (74a) is positioned at the same height as the open end (73a).

The exhaust joint 75 has a tubular shape and protrudes upward from a peripheral edge part of the opening (71c). The opening (71c) forms an exhaust port (OP7). The exhaust port (OP7) opens to the upper end part (72b) in the accommodating space 72, and exhausts a gas separated from the processing liquid. The exhaust port (OP7) is positioned above the second liquid feeding port (OP6). An upper end (75a) of the exhaust joint 75 is an open end that is open upward, and can be detachably connected to the exhaust path. That is, the exhaust joint 75 has the open end (75a) that can be connected to the exhaust path, is connected to the exhaust port (OP7), and extends upward outside the accommodating space 72.

As described above, the first liquid feeding joint 73, the second liquid feeding joint 74 and the exhaust joint 75 extend in the same direction outside the accommodating space 72. The housing 71, the first liquid feeding joint 73, the second liquid feeding joint 74 and the exhaust joint 75 are formed of, for example, a resin material.

The filter 76 is a tubular member that is formed of, for example, a non-woven fabric and is accommodated in the accommodating space 72 in a state of surrounding the first liquid feeding joint 73 and the second liquid feeding joint 74. The filter 76 partitions the interior of the accommodating space 72 into an inner side space (B1) and an outer side space (B2). The second liquid feeding port (OP6) opens in the inner side space (B1). The exhaust port (OP7) opens in the outer side space (B2).

The partition plate 77 has a flange shape that widens as it extends from the lower end (73b) of the first liquid feeding joint 73 toward an outer peripheral side. The partition plate 77 is positioned below the filter 76 and a peripheral edge of the partition plate 77 reaches an outer peripheral surface of the filter 76. By providing the partition plate 77, the first liquid feeding port (OP5) is communicatively connected to the outer side space (B2), without being communicatively connected to the inner side space (B1). The partition plate 77 is formed of, for example, a resin material same as that of the housing 71 and the like.

The filter device 70 that is structured as described above is used by connecting one of the open ends (73a, 74a) to an upstream side of the supply path of the processing liquid, connecting the other one of the open ends (73a, 74a) to a downstream side of the supply path of the processing liquid, and connecting the open end (75a) to the exhaust path.

In the case where the open end (73a) is connected to the upstream side of the supply path of the processing liquid and the open end (74a) is connected to the downstream side of the supply path of the processing liquid, the processing liquid flows from the first liquid feeding port (OP5) into accommodating space 72, passes below the partition plate 77 and spreads to the peripheral side, and flows into the lower end part of the outer side space (B2). The processing liquid that has flowed into the outer side space (B2) passes through the filter 76 while ascending, flows into the inner side space (B1), and flows out from the second liquid feeding port (OP6) to the outside of the accommodating space 72. In the outer side space (B2) that becomes an upstream side of the filter 76, a gas separated from the processing liquid emerges. The gas gathers at an upper portion of the outer side space (B2) and is exhausted from the exhaust port (OP7).

In the case where the open end (74a) is connected to the upstream side of the supply path of the processing liquid and the open end (73a) is connected to the downstream side of the supply path of the processing liquid, the processing liquid flows from the second liquid feeding port (OP6) into the inner side space (B1) of the accommodating space 72, passes through the filter 76 while descending, and flows into the outer side space (B2). The processing liquid that has flowed into the outer side space (B2) passes below the partition plate 77 and flows out from the first liquid feeding port (OP5) to the outside of the accommodating space 72. In the outer side space (B2) that becomes a downstream side of the filter 76, a gas separated from the processing liquid emerges. The gas gathers at an upper portion of the outer side space (B2) and is exhausted from the exhaust port (OP7).

In the filter device 70, a peripheral surface (72a) of the accommodating space 72 is formed in such a manner that the peripheral surface (72a) widens as it extends upward. As a result, on the lower side of the outer side space (B2), it becomes easy for the processing liquid to flow along the inner surface of the accommodating space 72.

In the filter device 70 illustrated in FIG. 10, the peripheral surface (72a) of the accommodating space 72 is formed in such a manner that the peripheral surface (72a) widens as it extends downward. In this case, on the upper side of the outer side space (B2), it becomes easy for the processing liquid to flow along the inner surface of the accommodating space 72.

### Second Embodiment

A main difference between a filter device (20A) according to a second embodiment and the filter device 20 according to the first embodiment is that, in the filter device (20A), a second liquid feeding joint (25A) is positioned inside the accommodating space 22.

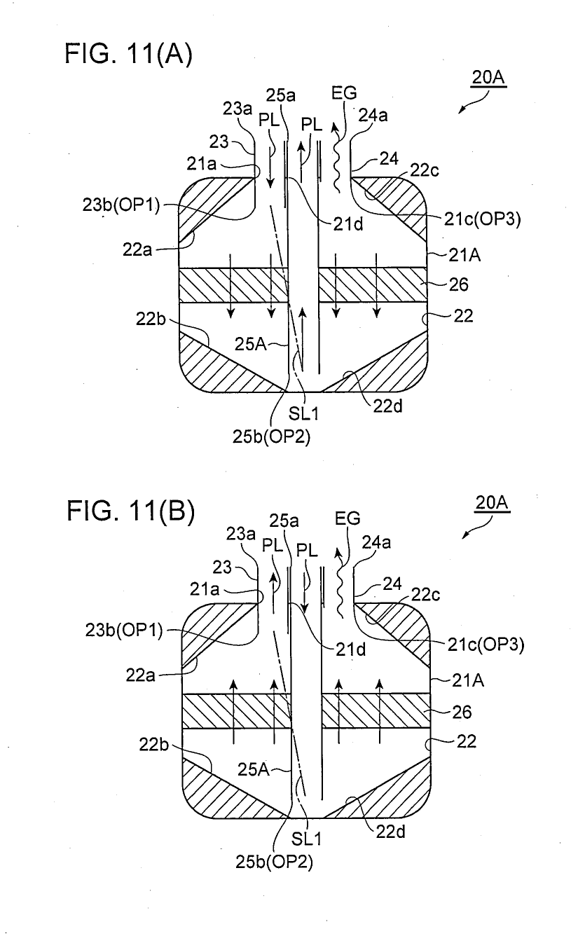

As illustrated in FIG. 11A and 11B, the filter device (20A) is obtained by replacing the housing 21 and the second liquid feeding joint 25 of the filter device 20 with a housing (21A) and the second liquid feeding joint (25A). The housing (21A) is obtained by eliminating the opening (21b) of the lower end part of the housing 21 and adding an opening (21d) on the upper end part of the housing 21.

The second liquid feeding joint (25A) has a tubular shape and protrudes upward and downward from a peripheral edge part of the opening (21d). The second liquid feeding joint (25A) penetrates through the filter 26, and a lower end (25b) of the second liquid feeding joint (25A) is positioned at the lower end part (22d) in the accommodating space 22. The lower end (25b) forms the second liquid feeding port (OP2). The second liquid feeding port (OP2) opens to the lower end part (22d) in the accommodating space 22, and introduces or leads out the processing liquid. An upper end (25a) of the second liquid feeding joint (25A) is an open end that is open upward, and can be detachably connected to the supply path. That is, the second liquid feeding joint (25A) has the open end (25a) that can be connected to the supply path, is connected to the second liquid feeding port (OP2), passes through inside the accommodating space 22 to penetrate through the filter 26, and extends upward outside the accommodating space 22.

FIG. 11A illustrates flow of the processing liquid (PL) in the case where the open end (23a) is connected to the upstream side of the supply path of the processing liquid and the open end (25a) is connected to the downstream side of the supply path of the processing liquid. In this case, the processing liquid (PL) flows in from the first liquid feeding port (OP1) to the accommodating space 22, descends to pass through the filter 26, and flows out from the second liquid feeding port (OP2) to the outside of the accommodating space 22. Foreign substances in the processing liquid (PL) are removed by the filter 26. On an upper side of the filter 26, the gas (EG) separated from the processing liquid (PL) emerges. Since the first liquid feeding port (OP1) is positioned below the exhaust port (OP3), the gas (EG) gathers around the first liquid feeding joint 23 and is exhausted from the exhaust port (OP3).

FIG. 11B illustrates flow of the processing liquid (PL) in the case where the open end (25a) is connected to the upstream side of the supply path of the processing liquid and the open end (23a) is connected to the downstream side of the supply path of the processing liquid. In this case, the processing liquid (PL) flows in from the second liquid feeding port (OP2) to the accommodating space 22, ascends to pass through the filter 26, and flows out from the first liquid feeding port (OP1) to the outside of the accommodating space 22. Foreign substances in the processing liquid (PL) are removed by the filter 26. On the upper side of the filter 26, the gas (EG) separated from the processing liquid (PL) emerges to gather around the first liquid feeding joint 23 and is exhausted from the exhaust port (OP3).

Similar to the filter device 20, the filter device (20A) can also be easily attached to and detached from the supply path of the processing liquid (PL) and the exhaust path, and the retention of the processing liquid (PL) can be suppressed. Further, the second liquid feeding joint (25A) passes through inside the accommodating space 22 to penetrate through the filter 26 and extends upward outside the accommodating space 22. Therefore, the first liquid feeding joint 23, the second liquid feeding joint (25A) and the exhaust joint 24 can all be formed in simple linear shapes.

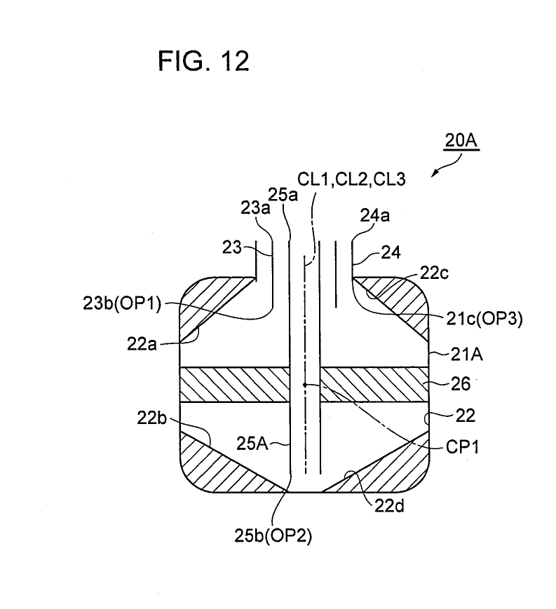

It is also possible to position the first liquid feeding joint 23 in a manner surrounding the second liquid feeding joint (25A), and to position the exhaust joint 24 in a manner surrounding the first liquid feeding joint 23. In association with this, it is also possible that the first liquid feeding port (OP1) has an annular shape that surrounds the second liquid feeding joint (25A) and the exhaust port (OP3) has an annular shape that surrounds the first liquid feeding joint 23 (see FIG. 12). In this case, the center axis line (CL1) of the first liquid feeding joint 23 [symbol] , a center axis line (CL2) of the second liquid feeding joint (25A) and the center axis line (CL3) of the exhaust joint 24 can all coincide with the center (CP1) of the filter 26. By making the center axis lines (CL1, CL2) of the first liquid feeding joint 23 and the second liquid feeding joint (25A) coincide with the center (CP1), variation in flow rates of the processing liquid (PL) corresponding to different portions of the filter 26 is suppressed. Therefore, the retention of the processing liquid (PL) can be further suppressed. By making the center axis line (CL3) of the exhaust joint 24 coincide with the center (CP1), the gas (EG) separated from the processing liquid (PL) can be further efficiently collected and exhausted.

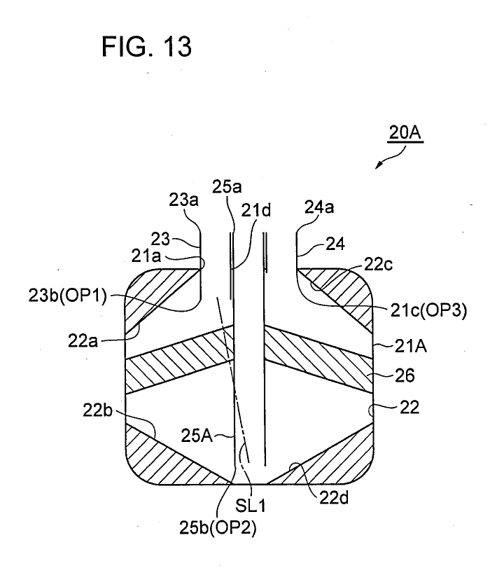

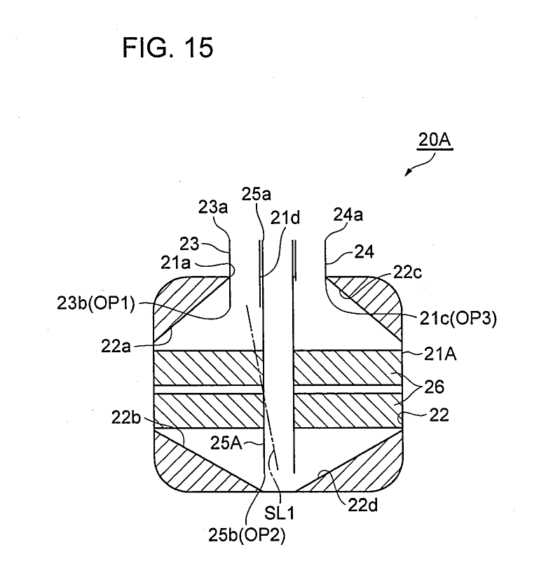

In the filter device (20A), the filter 26 may also have a cone shape with a center part raised toward the first liquid feeding port (OP1) (see FIG. 13) and may also have a cone shape with a center part raise toward the second liquid feeding port (OP2) (see FIG. 4). It is also possible to stack and position multiple the filters 26 in the accommodating space 22 (see FIG. 15).

### Third Embodiment

A main difference between a filter device 30 according to a third embodiment and the filter device 20 according to the first embodiment is that, in the filter device 30, the first liquid feeding port (OP1) and the second liquid feeding port (OP2) are positioned at two end parts in a horizontal direction and exhaust ports (OP3, OP4) are provided on both upstream side and downstream side of a filter 37.

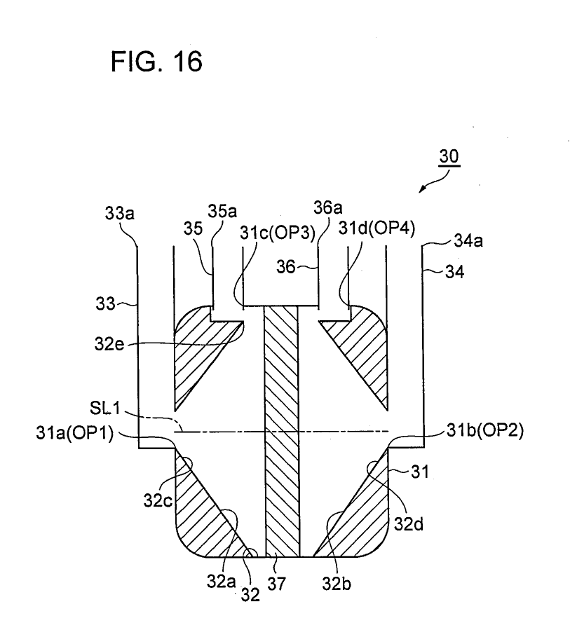

As illustrated in FIG. 16, the filter device 30 includes a housing 31, a first liquid feeding joint 33, a second liquid feeding joint 34, exhaust joints (35, 36) and the filter 37.

The housing 31 is a container that has therein an accommodating space 32. That is, the filter device 30 further includes the accommodating space 32. On the two end parts of the accommodating space 32 in the horizontal direction, openings (31a, 31b) are respectively provided. In the following, “left” and “right” refer to directions that match those of the drawings, and refer to directions that are defined in such a manner that the opening (31a) side is a left side and the opening (31b) side is a right side. The opening (31a) is positioned at a center of a left end part of the housing 31, and the opening (31b) is positioned at a center of a right end part of the housing 31. At an upper end part of the housing 31, openings (31c, 31d) are provided. The openings (31c, 31d) are positioned along a left-right direction.

The first liquid feeding joint 33 has a tubular shape. One end part of the first liquid feeding joint 33 is connected from the left side to the center of the left end part of the housing 31. The one end part of the first liquid feeding joint 33 opens rightward and is fixed to a peripheral edge part of the opening (31a). The opening (31a) forms the first liquid feeding port (OP1). The first liquid feeding port (OP1) opens to the left end part (32c) in the accommodating space 32, and introduces or leads out the processing liquid. The left end part (32c) includes a left end and its vicinity.

The first liquid feeding joint 33 passes around the accommodating space 32 and extends upward outside the accommodating space 32. An upper end (33a) of the first liquid feeding joint 33 is an open end that is open upward. That is, the first liquid feeding joint 33 has the open end (33a) that can be connected to the supply path of the processing liquid, is connected to the first liquid feeding port (OP1), and extends upward outside the accommodating space 32.

The second liquid feeding joint 34 has a tubular shape. One end part of the second liquid feeding joint 34 is connected from the right side to the center of the right end part of the housing 31. The one end part of the second liquid feeding joint 34 opens leftward and is fixed to a peripheral edge part of the opening (31b). The opening (31b) forms the second liquid feeding port (OP2). The second liquid feeding port (OP2) opens to the right end part (32d) in the accommodating space 32, and introduces or leads out the processing liquid. The right end part (32d) includes a right end and its vicinity.

The second liquid feeding joint 34 passes around the accommodating space 32 and extends upward outside the accommodating space 32. An upper end (34a) of the second liquid feeding joint 34 is an open end that is open upward. That is, the second liquid feeding joint 34 has the open end (34a) that can be connected to the supply path of the processing liquid, is connected to the second liquid feeding port (OP2), and extends upward outside the accommodating space 32. The open end (34a) is positioned at the same height as the open end (33a).

The exhaust joints (35, 36) each have a tubular shape and respectively protrude upward from peripheral edge parts of the openings (31c, 31d). The openings (31c, 31d) respectively form the exhaust ports (OP3, OP4). The exhaust ports (OP3, OP4) open to an upper end part (32e) in the accommodating space 32, and exhaust a gas separated from the processing liquid. Upper ends (35a, 36a) of the exhaust joints (35, 36) are open ends that are open upward, and can be detachably connected to the exhaust path. That is, the exhaust joints (35, 36) respectively have the open ends (35a, 36a) that can be connected to the exhaust path, are respectively connected to the exhaust ports (OP3, OP4), and respectively extend upward outside the accommodating space 32. The open ends (35a, 36a) are positioned at the same height as the open ends (33a, 34a).

As described above, the first liquid feeding joint 33, the second liquid feeding joint 34 and the exhaust joints (35, 36) extend in the same direction outside the accommodating space 32. The housing 31, the first liquid feeding joint 33, the second liquid feeding joint 34 and the exhaust joints (35, 36) are formed of, for example, a resin material.

The filter 37 is accommodated in an upright state with respect to the horizontal direction in the accommodating space 32. The filter 37 intersects a straight line (SL1) that passes through a center of the first liquid feeding port (OP1) and a center of the second liquid feeding port (OP2). A peripheral edge part of the filter 37 is fixed on an inner surface of the accommodating space 32. The filter 37 is positioned between the openings (31c, 31d). That is, the exhaust ports (OP3, OP4) are provided at two places than sandwich the filter 37.

An inner surface (32a) of the accommodating space 32 on the first liquid feeding port (OP1) side is formed in such a manner that the inner surface (32a) becomes closer to the filter 37 with increasing distance from the first liquid feeding port OP1. As an example, the inner surface (32a) forms a cone-like shape that gradually widens as it extends rightward.

An inner surface (32b) of the accommodating space 32 on the second liquid feeding port (OP2) side is formed in such a manner that the inner surface (32b) becomes closer to the filter 37 with increasing distance from the second liquid feeding port (OP2). As an example, the inner surface (32b) forms a cone-like shape that gradually widens as it extends leftward.

The filter device 30 that is structured as described above is used by connecting one of the open ends (33a, 34a) to an upstream side of the supply path of the processing liquid, connecting the other one of the open ends (33a, 34a) to a downstream side of the supply path of the processing liquid, and connecting the open ends (35a, 36a) to the exhaust path.

The processing liquid flows from one of the first liquid feeding port (OP1) and the second liquid feeding port (OP2) into the accommodating space 32, passes through the filter 37, and flows out from the other one of the first liquid feeding port (OP1) and the second liquid feeding port (OP2) to the outside of the accommodating space 32. Foreign substances in the processing liquid are removed by the filter 37. On both left and right sides of the filter 37, a gas separated from the processing liquid emerges. The gas gathers at the upper end part (32e) of the accommodating space 32 and is exhausted from the exhaust ports (OP3, OP4).

Similar to the filter device 20, the filter device 30 can also be easily attached to and detached from the supply path of the processing liquid and the exhaust path, and the retention of the processing liquid can be suppressed. Further, the exhaust ports (OP3, OP4) are provided at the two sides that sandwich the filter 37. Therefore, in either case where the processing liquid is caused to flow in from the first liquid feeding port (OP1) and flow out from the second liquid feeding port (OP2) or where the processing liquid is caused to flow in from the second liquid feeding port (OP2) and flow out from the first liquid feeding port (OP1), the exhaust ports (OP3, OP4) are positioned on both the upstream side and the downstream side of the filter 37. Therefore, both a gas separated from the processing liquid on the upstream side of the filter 37 and a gas separated from the processing liquid on the downstream side of the filter 37 can be exhausted.

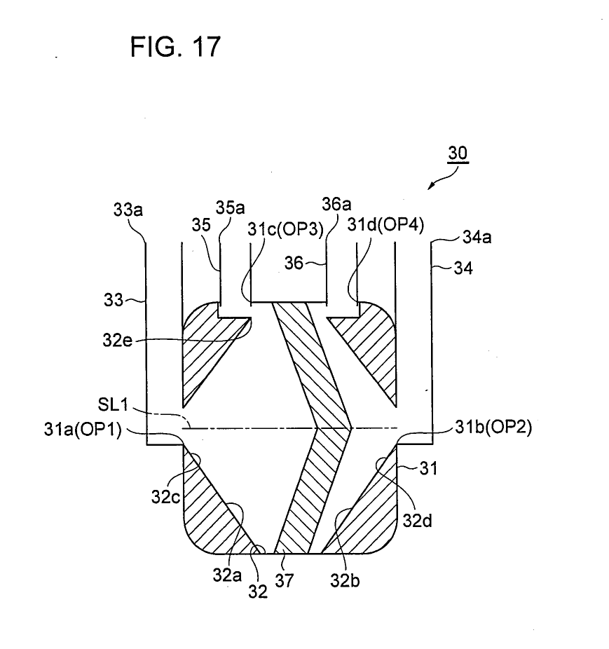

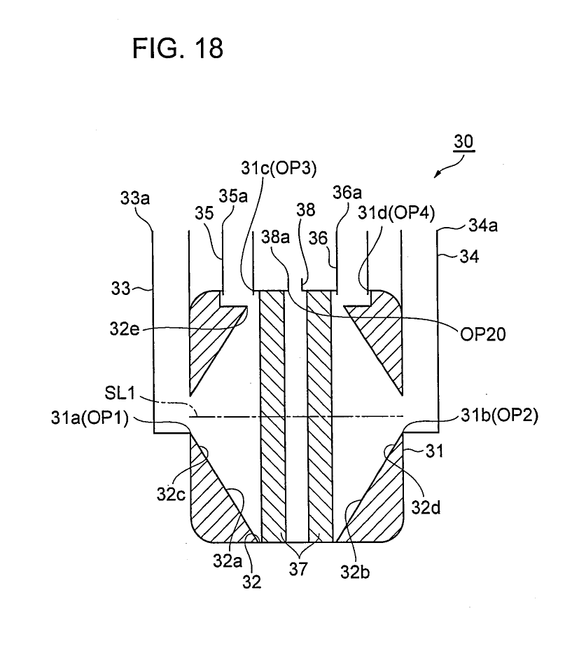

Also in the filter device 30, the filter 37 may also have a cone shape with a center part raised toward the first liquid feeding port (OP1) or the second liquid feeding port (OP2) (see FIG. 17). It is also possible to stack and position multiple the filters 37 in the accommodating space 32 (see FIG. 18). In this case, between the filters 37, an exhaust port (OP20) and an exhaust joint 38 may be further provided. The exhaust port (OP20) and the exhaust joint 38 are structured in a similar manner as the exhaust ports (OP3, OP4) and the exhaust joints (35, 36). The exhaust port (OP20) opens to the upper end part (32e) in the accommodating space 32, and exhausts the gas separated from the processing liquid. The exhaust joint 38 has an open end (38a) that can be connected to the exhaust path, is connected to the exhaust port (OP20), and extends upward outside the accommodating space 32. By providing the exhaust port (OP20) and the exhaust joint 38, air bubbles can be prevented from being accumulated between the filters 37. Therefore, decrease in filtration efficiency due to accumulation of air bubbles can be suppressed.

### Fourth Embodiment

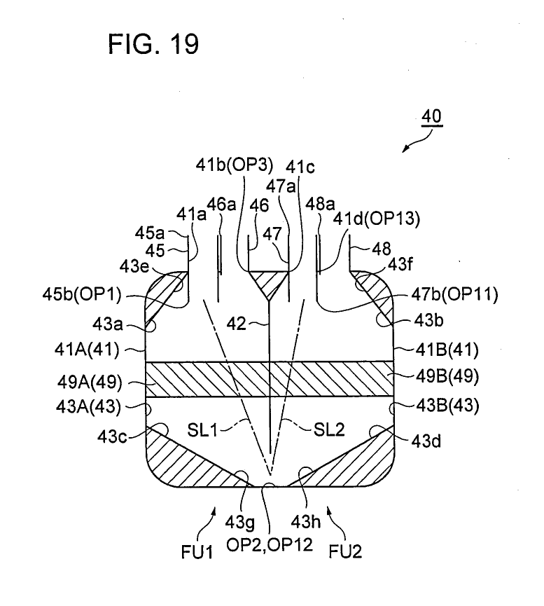

As illustrated in FIG. 19, a filter device 40 according to a fourth embodiment includes a housing 41, first liquid feeding joints (45, 47) and exhaust joints (46, 48).

The housing 41 is a container that has therein an accommodating space 43. The accommodating space 43 is partitioned into two accommodating spaces (43A, 43B) by a partition wall 42 that extends in the up-down direction. An upper end part of the partition wall 42 reaches an upper surface of the accommodating space 43 and a lower end part of the partition wall 42 is separated away from a bottom surface of the accommodating space 43. Therefore, the accommodating spaces (43A, 43B) are communicatively connected with each other on a lower side. In the following, in the housing 41, portions corresponding to the accommodating spaces (43A, 43B) are respectively referred to as housings (41A, 41B). “Left” and “right” refer to directions that match those of the drawings, and refer to directions that are defined in such a manner that the accommodating space (43A) side is a left side and the accommodating space (43B) side is a right side.

At a center of an upper end part of the housing (41A), openings (41a, 41b) are provided. At a center of an upper end part of the housing (41B), openings (41c, 41d) are provided.

The first liquid feeding joint 45 has a tubular shape and protrudes upward and downward from a peripheral edge part of the opening (41a). A lower end (45b) of the first liquid feeding joint 45 is positioned at an upper end part (43e) in the accommodating space (43A) and forms a first liquid feeding port (OP1). The first liquid feeding port (OP1) opens to the upper end part (43e) in the accommodating space (43A), and introduces or leads out a processing liquid. The upper end part (43e) includes an upper end and its vicinity. An upper end (45a) of the first liquid feeding joint 45 is an open end that is open upward, and can be detachably connected to the supply path of the processing liquid. That is, the first liquid feeding joint 45 has the open end (45a) that can be connected to the supply path, is connected to the first liquid feeding port (OP1), and extends upward outside the accommodating space (43A).

The exhaust joint 46 has a tubular shape and protrudes upward from a peripheral edge part of the opening (41b). The opening (41b) forms an exhaust port (OP3). The exhaust port (OP3) opens to the upper end part (43e) in the accommodating space (43A), and exhausts a gas separated from the processing liquid. The exhaust port (OP3) is positioned above the first liquid feeding port (OP1). An upper end (46a) of the exhaust joint 46 is an open end that is open upward, and can be detachably connected to the exhaust path. That is, the exhaust joint 46 has the open end (46a) that can be connected to the exhaust path, is connected to the exhaust port (OP3), and extends upward outside the accommodating space (43A). The open end (46a) is positioned at the same height as the open end (45a).

The first liquid feeding joint 47 has a tubular shape and protrudes upward and downward from a peripheral edge part of the opening (41c). A lower end (47b) of the first liquid feeding joint 47 is positioned at an upper end part (43f) in the accommodating space (43B) and forms a first liquid feeding port (OP11). The first liquid feeding port (OP11) opens to the upper end part (43f) in the accommodating space (43B), and introduces or leads out the processing liquid. The upper end part (43f) includes an upper end and its vicinity. An upper end (47a) of the first liquid feeding joint 47 is an open end that is open upward, and can be detachably connected to the supply path of the processing liquid. That is, the first liquid feeding joint 47 has the open end (47a) that can be connected to the supply path, is connected to the first liquid feeding port (OP11), and extends upward outside the accommodating space (43B). The open end (47a) is positioned at the same height as the open ends (45a, 46a).

The exhaust joint 48 has a tubular shape and protrudes upward from a peripheral edge part of the opening (41d). The opening (41d) forms an exhaust port (OP13). The exhaust port (OP13) opens to the upper end part (43f) in the accommodating space (43B), and exhausts a gas separated from the processing liquid. The exhaust port (OP13) is positioned above the first liquid feeding port (OP11). An upper end (48a) of the exhaust joint 48 is an open end that is open upward, and can be detachably connected to the exhaust path. That is, the exhaust joint 48 has the open end (48a) that can be connected to the exhaust path, is connected to the exhaust port (OP13), and extends upward outside the accommodating space (43B). The open end (48a) is positioned at the same height as the open ends (45a, 46a, 47a).

As described above, the first liquid feeding joints (45, 47) and the exhaust joints (46, 48) extend in the same direction outside the accommodating spaces (43A, 43B). The housing 41, the first liquid feeding joints (33, 45, 47) and the exhaust joints (46, 48) are formed of, for example, a resin material.

As described above, the lower end part of the partition wall 42 is separated away from the bottom surface of the accommodating space 43. A space between the lower end of the partition wall 42 and the bottom surface of the accommodating space 43 forms second liquid feeding ports (OP2, OP12). The second liquid feeding port (OP2) opens to a lower end part (43g) in the accommodating space (43A), and introduces or leads out the processing liquid. The second liquid feeding port (OP12) opens to a lower end part (43h) in the accommodating space (43B), and introduces or leads out the processing liquid. The lower end parts (43g, 43h) each include a lower end and its vicinity. The space between the lower end of the partition wall 42 and the bottom surface of the accommodating space 43 serves as both the second liquid feeding ports (OP2, OP12). Therefore, the second liquid feeding ports (OP2, OP12) are connected to each other.

The filter 49 is a sheet-like member that is formed of, for example, a non-woven fabric and is accommodated in the accommodating space 43 in a state of being orthogonal to a vertical direction. The filter 49 is partitioned by the partition wall 42 into two regions. In the following, the region accommodated in the accommodating space (43A) is referred to as a filter (49A), and the region accommodated in the accommodating space (43B) is referred to as a filter (49B).

The filter (49A) intersects a straight line (SL1) that passes through a center of the first liquid feeding port (OP1) and a center of the second liquid feeding port (OP2). A peripheral edge part of the filter (49A) is fixed on an inner surface of the accommodating space (43A). The filter (49B) intersects a straight line (SL2) that passes through a center of the first liquid feeding port (OP11) and a center of the second liquid feeding port (OP12). A peripheral edge part of the filter (49B) is fixed on an inner surface of the accommodating space (43B).

An inner surface (43a) of the accommodating space (43A) on the first liquid feeding port (OP1) side is formed in such a manner that the inner surface (43a) becomes closer to the filter (49A) with increasing distance from the first liquid feeding port (OP1). As an example, the inner surface (43a) forms a cone-like shape that gradually widens as it extends downward.

An inner surface (43b) of the accommodating space (43B) on the first liquid feeding port (OP11) side is formed in such a manner that the inner surface (43b) becomes closer to the filter (49B) with increasing distance from the first liquid feeding port (OP11). As an example, the inner surface (43b) forms a cone-like shape that gradually widens as it extends downward.

An inner surface (43c) of the accommodating space (43A) on the lower end side is formed in such a manner that the inner surface (43c) becomes closer to the filter (49A) with increasing distance from the second liquid feeding port (OP2). An inner surface (43d) of the accommodating space (43B) on the lower end side is formed in such a manner that the inner surface (43d) becomes closer to the filter (49B) with increasing distance from the second liquid feeding port (OP12). As an example, an entire surface that combines the inner surfaces (43c, 43d) forms a cone-like shape that gradually widens as it extends upward.

The accommodating space (43A), the first liquid feeding port (OP1), the second liquid feeding port (OP2), the exhaust port (OP3), the first liquid feeding joint 45 and the exhaust joint 46 form a filter component (FU1). The accommodating space (43B), the first liquid feeding port (OP11), the second liquid feeding port (OP12), the exhaust port (OP13), the first liquid feeding joint 47 and the exhaust joint 48 form a filter component (FU2). That is, the filter device 40 includes two filter components (FU1, FU2), each of which has an accommodating space, a first liquid feeding port, a second liquid feeding port, an exhaust port, a filter, a first liquid feeding joint and an exhaust joint.

The filter device 40 is used by connecting one of the open ends (45a, 47a) to an upstream side of the supply path of the processing liquid, connecting the other one of the open ends (45a, 47a) to a downstream side of the supply path of the processing liquid, and connecting the open ends (46a, 48a) to the exhaust path.

In the case where the open end (45a) is connected to the upstream side of the supply path of the processing liquid and the open end (47a) is connected to the downstream side of the supply path of the processing liquid, the processing liquid flows from the first liquid feeding port (OP1) into the filter component (FU1), descends to pass through the filter (49A), and passes through the second liquid feeding ports (OP2, OP12) to flow into the filter component (FU2). The processing liquid that has flowed into the filter component (FU2) ascends to pass through the filter (49B), and flows out from the first liquid feeding port (OP11). That is, the processing liquid respectively passes through the filters (49A, 49B) in the two filter components (FU1, FU2). Therefore, foreign substances can be more reliably removed.

On an upper side of the filter (49A), a gas separated from the processing liquid emerges. The gas gathers around the first liquid feeding joint 45 and is exhausted from the exhaust port (OP3). On an upper side of the filter (49B), a gas separated from the processing liquid emerges. The gas gathers around the first liquid feeding joint 47 and is exhausted from the exhaust port (OP13). Therefore, both the gas separated from the processing liquid on the upstream side of the filter (49A) and the gas separated from the processing liquid on the downstream side of the filter (49B) can be exhausted.

Also in the case where the open end (47a) is connected to the upstream side of the supply path of the processing liquid and the open end (45a) is connected to the downstream side of the supply path of the processing liquid, the filter device 40 similarly functions.

In either one of the filter components (FU1, FU2), the first liquid feeding port and the second liquid feeding port are formed on opposite sides of each other, and the filter intersects a straight line that passes through a center of the first liquid feeding port and a center of the second liquid feeding port. That is, the first liquid feeding port, the filter and the second liquid feeding port are positioned along one straight line. As a result, the flow of the processing liquid flowing into the accommodating space, passing through the filter and flowing out to the outside of the accommodating space is simplified. Therefore, the retention of the processing liquid in the accommodating space can be suppressed. The second liquid feeding ports of the two filter components (FU1, FU2) are connected to each other. Further, all of the first liquid feeding joints and the exhaust joints extend in the same direction (upward) outside the accommodating space. Therefore, the filter device 40 can be easily attached to and detached from the supply path of the processing liquid and the exhaust path. One of the filter components (FU1, FU2) is connected to the second liquid feeding port of the other one of the filter components (FU1, FU2), and functions as a second liquid feeding joint that passes around the accommodating space and extends upward outside of the accommodating space.

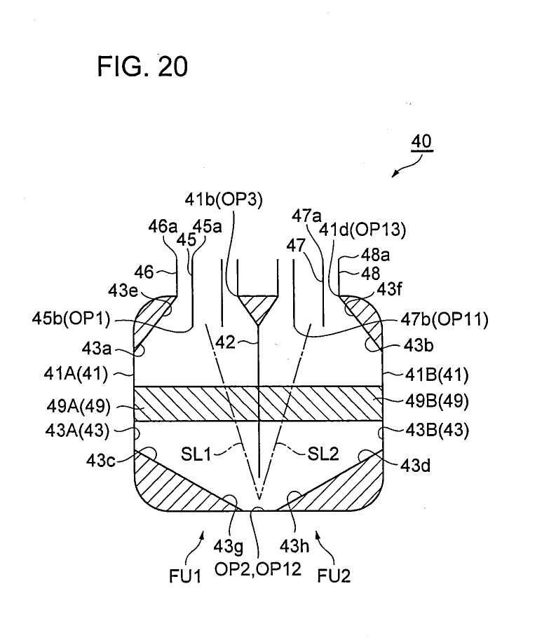

Also in the filter device 40, it is also possible to position the exhaust joint 46 in a manner surrounding the first liquid feeding joint 45 and to position the exhaust joint 48 in a manner surrounding the first liquid feeding joint 47. In association with this, it is also possible that the exhaust port (OP3) has an annular shape that surrounds the first liquid feeding joint 45 and the exhaust port (OP13) has an annular shape that surrounds the first liquid feeding joint 47 (see FIG. 20).

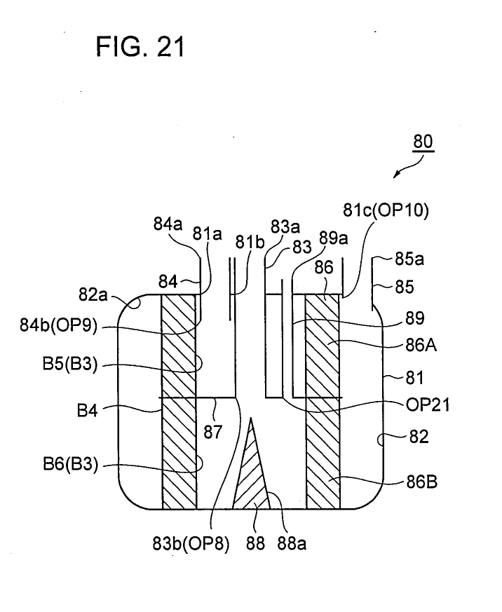

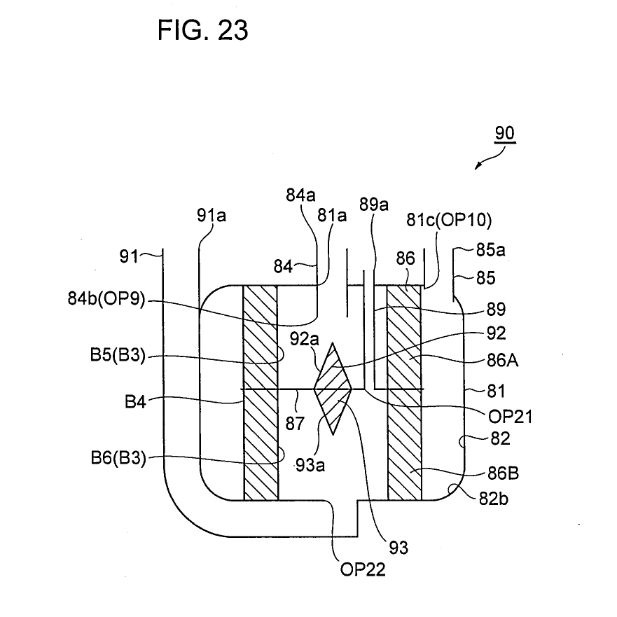

In the filter device 40, the one filter 49 is partitioned into multiple regions (49A, 49B), and a flow path is formed that sequentially passes through the respective regions (49A, 49B). Such a configuration is also applicable to filter devices of other embodiments. In the following, with reference to FIGS. 21 and 23, application examples are described.

A filter device 80 illustrated in FIG. 21 includes a housing 81, a first liquid feeding joint 83, a second liquid feeding joint 84, an exhaust joint 85, a filter 86 and a partition plate 87.

The housing 81 is a container that has therein an accommodating space 82. That is, the filter device 80 further includes the accommodating space 82. At a center of an upper end part of the housing 81, openings (81a, 81b) are provided. On a peripheral edge side of an upper end part of the housing 81, an opening (81c) is provided.

The first liquid feeding joint 83 has a tubular shape and protrudes upward and downward from a peripheral edge part of the opening (81b). A lower end (83b) of the first liquid feeding joint 83 is positioned at a center part in the accommodating space 82 and forms a first liquid feeding port (OP8). The first liquid feeding port (OP8) opens to the center part in the accommodating space 82, and introduces or leads out the processing liquid. An upper end (83a) of the first liquid feeding joint 83 is an open end that is open upward, and can be detachably connected to the supply path of the processing liquid. That is, the first liquid feeding joint 83 has the open end (83a) that can be connected to the supply path, is connected to the first liquid feeding port (OP8), and extends upward outside the accommodating space 82.

The second liquid feeding joint 84 has a tubular shape and protrudes upward and downward from a peripheral edge part of the opening (81a). A lower end (84b) of the second liquid feeding joint 84 is positioned at an upper end part (82a) in the accommodating space 82 and forms a second liquid feeding port (OP9). The second liquid feeding port (OP9) opens to the upper end part (82a) in the accommodating space 82, and introduces or leads out the processing liquid. The upper end part (82a) includes an upper end and its vicinity. An upper end (84a) of the second liquid feeding joint 84 is an open end that is open upward, and can be detachably connected to the supply path of the processing liquid. That is, the second liquid feeding joint 84 has the open end (84a) that can be connected to the supply path, is connected to the second liquid feeding port (OP9), and extends upward outside the accommodating space 82. The open end (84a) is positioned at the same height as the open end (83a).

The exhaust joint 85 has a tubular shape and protrudes upward from a peripheral edge part of the opening (81c). The opening (81c) forms an exhaust port (OP10). The exhaust port (OP10) opens to the upper end part (82a) in the accommodating space 82, and exhausts a gas separated from the processing liquid. The exhaust port (OP10) is positioned above the second liquid feeding port (OP9). An upper end (85a) of the exhaust joint 85 is an open end that is open upward, and can be detachably connected to the exhaust path. That is, the exhaust joint 85 has the open end (85a) that can be connected to the exhaust path, is connected to the exhaust port (OP10), and extends upward outside the accommodating space 82.

As described above, the first liquid feeding joint 83, the second liquid feeding joint 84 and the exhaust joint 85 extend in the same direction outside the accommodating space 82. The housing 81, the first liquid feeding joint 83, the second liquid feeding joint 84 and the exhaust joint 85 are formed of, for example, a resin material.

The filter 86 is a tubular member that is formed of, for example, a non-woven fabric and is accommodated in the accommodating space 82 in a state of surrounding the first liquid feeding joint 83 and the second liquid feeding joint 84. The filter 86 partitions the accommodating space 82 into an inner side space (B3) and an outer side space (B4). The first liquid feeding port (OP8) and the second liquid feeding port (OP9) open in the inner side space (B3). The exhaust port (OP10) opens in the outer side space (B4).

The partition plate 87 has a flange shape that widens as it extends from the lower end (83b) of the first liquid feeding joint 83 toward an outer peripheral side. The partition plate 87 partitions the filter 86 into two regions and a peripheral edge of the partition plate 87 reaches an outer peripheral surface of the filter 86. In the following, the region on the upper side of the partition plate 87 is referred to as a filter (86A), and the region on the lower side of the partition plate 87 is referred to as a filter (86B). The inner side space (B3) is partitioned by the partition plate 87 into an upper side space (B5) and a lower side space (B6). The partition plate 87 is formed of, for example, a resin material same as that of the housing 81 and the like.

At a center of a bottom surface of the accommodating space 82, a projection part 88 that projects upward is provided. An upper end of the projection part 88 is positioned below the first liquid feeding port (OP8). The projection part 88 has a cone shape, and a surface of the projection part 88 forms an inner surface (88a) of the accommodating space 82 on the first liquid feeding port (OP8) side. The inner surface (88a) becomes closer to the filter 86 with increasing distance from the first liquid feeding port (OP8).

The filter device 80 that is structured as described above is used by connecting one of the open ends (83a, 84a) to an upstream side of the supply path of the processing liquid, connecting the other one of the open ends (83a, 84a) to a downstream side of the supply path of the processing liquid, and connecting the open end (85a) to the exhaust path.

In the case where the open end (83a) is connected to the upstream side of the supply path of the processing liquid and the open end (84a) is connected to the downstream side of the supply path of the processing liquid, the processing liquid flows from the first liquid feeding port (OP8) into the lower side space (B6) of the accommodating space 82, spreads to a peripheral edge side below the partition plate 87, and passes through the filter (86B) to flow into the outer side space (B4). The processing liquid that has flowed into the outer side space (B4) passes through the filter (86A) while ascending, flows into the upper side space (B5), and flows out from the second liquid feeding port (OP9) to the outside of the accommodating space 82. In the outer side space (B4), a gas separated from the processing liquid emerges. The gas gathers at an upper portion of the outer side space (B4) and is exhausted from the exhaust port (OP10).

In the case where the open end (84a) is connected to the upstream side of the supply path of the processing liquid and the open end (83a) is connected to the downstream side of the supply path of the processing liquid, the processing liquid flows from the second liquid feeding port (OP9) into the upper side space (B5) in the accommodating space 82, passes through the filter (86A) while descending, and flows into the outer side space (B4). The processing liquid that has flowed into the outer side space (B4) passes through the filter (86B) while descending, flows into the lower side space (B6), and flows out from the first liquid feeding port (OP8) to the outside of the accommodating space 82. Also in this case, a gas separated from the processing liquid gathers at the upper portion of the outer side space (B4) and is exhausted from the exhaust port (OP10).

According to the filter device 80, the one filter 86 is partitioned into multiple regions (86A, 86B), and the processing liquid sequentially passes through the regions (86A, 86B). Therefore, foreign substances in the processing liquid can be more reliably removed.

The inner surface (88a) of the accommodating space 82 on the first liquid feeding port (OP8) side is formed in such a manner that the inner surface (88a) becomes closer to the filter 86 with increasing distance from the first liquid feeding port (OP8). As a result, it becomes easy for the processing liquid to flow along the inner surface of the accommodating space 82. Therefore, the retention of the processing liquid can be suppressed.

In order to allow a gas separated from the processing liquid in the lower side space of the partition plate 87 to be exhausted, an exhaust port (OP21) and an exhaust joint 89 may be further provided. The exhaust port (OP21) and the exhaust joint 89 are structured in a similar manner as the first liquid feeding port (OP8) and the first liquid feeding joint 83. The exhaust port (OP21) opens to the center part in the accommodating space 82, and exhausts the gas separated from the processing liquid. The exhaust joint 89 has an open end (89a) that can be connected to the exhaust path, is connected to the exhaust port (OP21), and extends upward outside the accommodating space 82. In this case, both a gas separated from the processing liquid on an upstream side of the filter 86 and a gas separated from the processing liquid on a downstream side of the filter 86 can be exhausted.

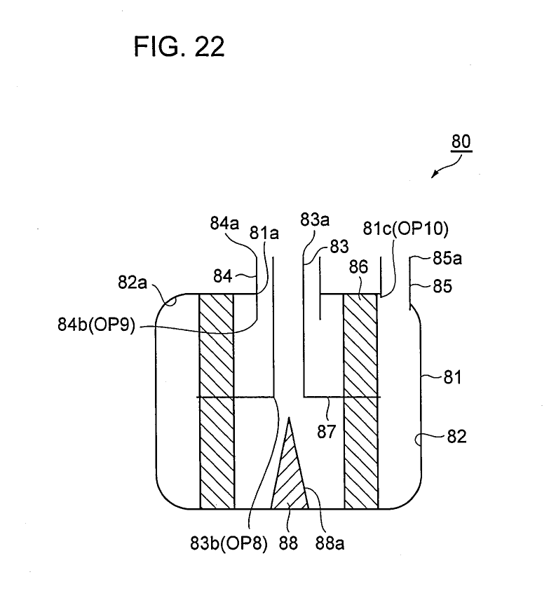

The second liquid feeding joint 84 may also be positioned in a manner surrounding the first liquid feeding joint 83. In association with this, the second liquid feeding port (OP9) may also have an annular shape that surrounds the first liquid feeding joint 83 (see FIG. 22).

A filter device 90 illustrated in FIG. 23 is obtained by replacing the first liquid feeding port (OP8) and the first liquid feeding joint 83 of the filter device 80 with a first liquid feeding port (OP22) and a first liquid feeding joint 91. The first liquid feeding port (OP22) and the first liquid feeding joint 91 are structured in a similar manner as the second liquid feeding port (OP2) and the second liquid feeding joint 25 of the filter device 20. That is, the first liquid feeding port (OP22) opens to the lower end part (82b) in the accommodating space 82, and introduces or leads out the processing liquid. The lower end part (82b) includes a lower end and its vicinity. The first liquid feeding joint 91 has the open end (91a) that can be connected to the supply path, is connected to the first liquid feeding port (OP22), and extends upward outside the accommodating space 82.

In the filter device 90, at a center of an upper surface of the partition plate 87, a projection part 92 that projects upward is provided. An upper end of the projection part 92 is positioned below the second liquid feeding port (OP9). The projection part 92 has a cone shape, and a surface of the projection part 92 forms an inner surface (92a) of the accommodating space 82 on the second liquid feeding port (OP9) side. The inner surface (92a) becomes closer to the filter 86 with increasing distance from the second liquid feeding port (OP9). At a center of a lower surface of the partition plate 87, a projection part 93 that projects downward is provided. A lower end of the projection part 93 is positioned above the first liquid feeding port (OP22). The projection part 93 has a downward cone shape, and a surface of the projection part 93 forms an inner surface (93a) of the accommodating space 82 on the first liquid feeding port (OP22) side. The inner surface (93a) becomes closer to the filter 86 with increasing distance from the first liquid feeding port (OP22).

Also in the filter device 90, the one filter 86 is partitioned into multiple regions (86A, 86B), and the processing liquid sequentially passes through the regions 86A, 86B. Therefore, foreign substances in the processing liquid can be more reliably removed.

The inner surface (93a) of the accommodating space 82 on the first liquid feeding port (OP22) side is formed in such a manner that the inner surface (93a) becomes closer to the filter 86 with increasing distance from the first liquid feeding port (OP22). The inner surface (92a) of the accommodating space 22 on the second liquid feeding port (OP9) side is formed in such a manner that the inner surface (92a) becomes closer to the filter 86 with increasing distance from the second liquid feeding port (OP9). As a result, it becomes easy for the processing liquid to flow along the inner surface of the accommodating space 82. Therefore, the retention of the processing liquid can be suppressed.

In the above, the embodiments have been described. However, the present invention is not limited to the above-described embodiments, but various modifications are possible within the scope without departing from the spirit of the present invention. For example, the respective elements of the filter devices (20, 20A, 30, 40, 70, 80, 90) may be appropriately combined and adopted. Further, the filter devices (20, 20A, 30, 40, 70, 80, 90) are also applicable to coating of an adhesive or coating of a Si-based insulation region forming agent, or the like.

A filter device of which an inlet, an outlet and a vent all extend in the same direction can be easily attached to and detached from a supply path of a processing liquid and an exhaust path. However, retention of the processing liquid may occur particularly on an upper side in a housing. In the case, foreign substances accumulated in the retained processing liquid may abruptly flow out and cause deterioration in quality of a supply target.

A filter device according to an embodiment of the present invention can be easily attached to and detached from a supply path of a processing liquid and an exhaust path, and retention of the processing liquid can be suppressed.

A filter device according to an embodiment of the present invention includes: an accommodating space; a first liquid feeding port and a second liquid feeding port that respectively open to two end parts in the accommodating space, and introduce or lead out a processing liquid for a semiconductor manufacturing process; an exhaust port that opens in the accommodating space and exhausts a gas separated from the processing liquid; a filter that is accommodated in the accommodating space in a state intersecting a straight line that passes through a center of the first liquid feeding port and a center of the second liquid feeding port; a tubular first liquid feeding joint that has an open end that can be connected to a supply path of the processing liquid, and is connected to the first liquid feeding port; a tubular second liquid feeding joint that has an open end that can be connected to the supply path of the processing liquid, and is connected to the second liquid feeding port; and a tubular exhaust joint that has an open end that can be connected to an exhaust path, and is connected to the exhaust port. The first liquid feeding joint, the second liquid feeding joint and the exhaust joint extend in a same direction outside the accommodating space.

In the filter device, the processing liquid that is introduced from one of the first liquid feeding port and the second liquid feeding port passes through the filter and is led out from the other one of the first liquid feeding port and the second liquid feeding port. Foreign substances in the processing liquid are removed by the filter. The first liquid feeding port and the second liquid feeding port are formed on opposite sides of each other, and the filter intersects the straight line that passes through the center of the first liquid feeding port and the center of the second liquid feeding port. That is, the first liquid feeding port, the filter and the second liquid feeding port are positioned along one straight line. As a result, the flow of the processing liquid flowing into the accommodating space, passing through the filter and flowing out to the outside of the accommodating space is simplified. Therefore, the retention of the processing liquid in the accommodating space can be suppressed. The first liquid feeding joint, the second liquid feeding joint and the exhaust joint are respectively connected to the first liquid feeding port, the second liquid feeding port and the exhaust port, and these joints extend in the same direction outside the accommodating space. Therefore, even when the first liquid feeding port and the second liquid feeding port are formed on opposite sides of each other, the filter device can be easily attached to and detached from the supply path of the processing liquid and the exhaust path.

It is also possible that the first liquid feeding port and the exhaust port open to an upper end part in the accommodating space, the second liquid feeding port opens to a lower end part in the accommodating space, the filter is accommodated in the accommodating space in a state intersecting a vertical direction, the first liquid feeding joint and the exhaust joint extend upward outside the accommodating space, and the second liquid feeding joint passes around the accommodating space to extend upward outside the accommodating space. In this case, the first liquid feeding port and the exhaust port open to the upper end part in the accommodating space. Therefore, the first liquid feeding joint and the exhaust joint, which extend upward, can be formed in simple linear shapes. When the processing liquid is caused to flow in from the first liquid feeding port and flow out from the second liquid feeding port, the exhaust port is positioned on an upstream side of the filter. Therefore, a gas separated from the processing liquid can be exhausted on the upstream side of the filter. When the processing liquid is caused to flow in from the second liquid feeding port and flow out from the first liquid feeding port, the exhaust port is positioned on a downstream side of the filter. Therefore, a gas separated from the processing liquid can be exhausted on the downstream side of the filter.

It is also possible that the exhaust joint is positioned in a manner surrounding the first liquid feeding joint, and the exhaust port has an annular shape that surrounds the first liquid feeding joint. In this case, center axis lines of both the first liquid feeding joint and the exhaust joint can coincide with a center of the filter. By making the center axis line of the first liquid feeding joint coincide with the center of the filter, variation in flow rates of the processing liquid corresponding to different portions of the filter is suppressed. Therefore, the retention of the processing liquid can be further suppressed. By making the center axis line of the exhaust joint coincide with the center of the filter, the gas separated from the processing liquid can be efficiently collected and exhausted.

It is also possible that the first liquid feeding port and the exhaust port open to an upper end part in the accommodating space, the second liquid feeding port opens to a lower end part in the accommodating space, the filter is accommodated in the accommodating space in a state intersecting the vertical direction, the first liquid feeding joint and the exhaust joint extend upward outside the accommodating space, and the second liquid feeding joint passes through inside the accommodating space to penetrate through the filter and extends upward outside the accommodating space. In this case, the first liquid feeding joint, the second liquid feeding joint and the exhaust joint can all be made in simple linear shapes.

It is also possible that the first liquid feeding joint is positioned in a manner surrounding the second liquid feeding joint, the exhaust joint is positioned surrounding the first liquid feeding joint, the first liquid feeding port has an annular shape that surrounds the second liquid feeding joint, and the exhaust port has an annular shape that surrounds the first liquid feeding joint. In this case, center axis lines of all of the first liquid feeding joint, the second liquid feeding joint and the exhaust joint can coincide with a center of the filter. By making the center axis lines of the first liquid feeding joint and the second liquid feeding joint coincide with the center of the filter, variation in flow rates of the processing liquid corresponding to different portions of the filter is suppressed. Therefore, the retention of the processing liquid can be further suppressed. By making the center axis line of the exhaust joint coincide with the center of the filter, the gas separated from the processing liquid can be efficiently collected and exhausted.

It is also possible that the first liquid feeding port and the second liquid feeding port respectively open to two end parts in the accommodating space in a horizontal direction, the filter is accommodated in the accommodating space in an upright state with respect to the horizontal direction, exhaust ports are provided at an upper end part of the accommodating space at multiple places that sandwich the filter, exhaust joints extend upward outside the accommodating space, the first liquid feeding joint and the second liquid feeding joint respectively pass around the accommodating space to extend upward outside the accommodating space. In this case, in either case where the processing liquid is caused to flow in from the first liquid feeding port and flow out from the second liquid feeding port or where the processing liquid is caused to flow in from the second liquid feeding port and flow out from the first liquid feeding port, the exhaust ports are positioned on both an upstream side and a downstream side of the filter. Therefore, both a gas separated from the processing liquid on the upstream side of the filter and a gas separated from the processing liquid on the downstream side of the filter can be exhausted.

It is also possible that two filter components are provided that are adjacent to each other in a horizontal direction, each of which includes: an accommodating space; a first liquid feeding port that opens to an upper end part in the accommodating space, and introduces or leads out a processing liquid for a semiconductor manufacturing process; a second liquid feeding port that opens to a lower end part in the accommodating space, and introduces or leads out the processing liquid; an exhaust port that opens to an upper end part in the accommodating space and exhausts a gas separated from the processing liquid; a filter that is accommodated in the accommodating space in a state intersecting a straight line that passes through a center of the first liquid feeding port and a center of the second liquid feeding port; a tubular first liquid feeding joint that has an open end that can be connected to a supply path of the processing liquid, and is connected to the first liquid feeding port; and a tubular exhaust joint that has an open end that can be connected to an exhaust path, and is connected to the exhaust port, the first liquid feeding joint and the exhaust joint of each of the two filter components extend upward outside the accommodating space, and the second liquid feeding ports of the two filter components are connected to each other.

In this case, the processing liquid that has flowed in from the first liquid feeding port of one filter component descents to pass through the filter, and flows from the second liquid feeding port into the other filter component. The processing liquid that has flowed into the other filter component ascends to pass through the filter, and flows out from the first liquid feeding port. That is, the processing liquid respectively passes through the filters in the two filter components. Therefore, foreign substances can be more reliably removed.

In each of the two filter components, the first liquid feeding port and the second liquid feeding port are formed on opposite sides of each other, and the filter intersects a straight line that passes through a center of the first liquid feeding port and a center of the second liquid feeding port. That is, the first liquid feeding port, the filter and the second liquid feeding port are positioned along one straight line. As a result, the flow of the processing liquid flowing into the accommodating space, passing through the filter and flowing out to the outside of the accommodating space is simplified. Therefore, the retention of the processing liquid in the accommodating space can be suppressed. The second liquid feeding ports of the two filter components are connected to each other. Further, all of the first liquid feeding joints and the exhaust joints extend in the same direction (upward) outside the accommodating space. Therefore, the filter device 40 can be easily attached to and detached from the supply path of the processing liquid and the exhaust path. One filter component is connected to the second liquid feeding port of the other filter component, and functions as a second liquid feeding joint that passes around the accommodating space and extends upward outside of the accommodating space.

It is also possible that an inner surface of the accommodating space on the first liquid feeding port side is formed in such a manner that the inner surface becomes closer to the filter with increasing distance from the first liquid feeding port, and an inner surface of the accommodating space on the second liquid feeding port side is formed in such a manner that the inner surface becomes closer to the filter with increasing distance from the second liquid feeding port. In this case, it becomes easy for the processing liquid to flow along the inner surface of the accommodating space. Therefore, the retention of the processing liquid can be further suppressed.

It is also possible that the filter has a cone shape with a center part raised toward a liquid feeding port from which the processing liquid is introduced, the liquid feeding port being one the first liquid feeding port and the second liquid feeding port. It is also possible that the filter has a cone shape with a center part raised toward a liquid feeding port from which the processing liquid is led out, the liquid feeding port being one the first liquid feeding port and the second liquid feeding port.

The filter device according to an embodiment of the present invention can be easily attached to and detached from a supply path of a processing liquid and an exhaust path, and retention of the processing liquid can be suppressed.

Obviously, numerous modifications and variations of the present invention are possible in light of the above teachings. It is therefore to be understood that within the scope of the appended claims, the invention may be practiced otherwise than as specifically described herein.

What is claimed is:

1. A filter device, comprising:
a housing having an accommodating space;
a filter accommodated in the accommodating space of the housing;
a first tubular joint connected to a first liquid feeding port of the housing and having an open end configured to be connected to a supply path of a processing liquid for a semiconductor manufacturing process;
a second tubular joint connected to a second liquid feeding port of the housing and having an open end configured to be connected to the supply path of the processing liquid; and
a tubular exhaust joint connected to an exhaust port of the housing and having an open end configured to be connected to an exhaust path,
wherein the first and the second liquid feeding ports are configured to introduce or discharge the processing liquid and positioned such that the first and the second liquid feeding ports have openings to opposite end portions of the accommodating space, respectively, the exhaust port is configured to exhaust gas separated from the processing liquid and positioned such that the exhaust port has an opening to the accommodating space, the filter is accommodated in the accommodating space such that the filter is intersecting a straight line passing through a center of the first liquid feeding port and a center of the second liquid feeding port, and the first tubular joint, the second tubular joint and the tubular exhaust joint are formed to extend in a same direction outside the accommodating space of the housing.

2. The filter device according to claim 1, wherein the openings of the first liquid feeding port and the exhaust port are formed on an upper end portion of the accommodating space, the opening of the second liquid feeding port is formed on a lower end portion of the accommodating space, the filter is positioned in the accommodating space such that the filter is intersecting in a vertical direction with respect to the straight line, the first tubular joint and the tubular exhaust joint are extending out and upward with respect to the accommodating space, and the second tubular joint is passing around the accommodating space and extending out and upward with respect to the accommodating space.

3. The filter device according to claim 2, wherein the tubular exhaust joint is formed to surround the first tubular joint, and the exhaust port has a ring shape surrounding the first liquid feeding port.

4. The filter device according to claim 1, wherein the openings of the first liquid feeding port and the exhaust port are formed on an upper end portion of the accommodating space, the opening of the second liquid feeding port is formed on a lower end portion of the accommodating space, the filter is positioned in the accommodating space such that the filter is intersecting in a vertical direction with respect to the straight line, the first tubular joint and the tubular exhaust joint are extending out and upward with respect to the accommodating space, and the second tubular joint is passing inside and through the accommodating space and extending out and upward with respect to the accommodating space.

5. The filter device according to claim 4, wherein the first tubular joint is formed to surround the second tubular joint, the tubular exhaust joint is formed to surround the first tubular joint, the first liquid feeding port has a ring shape surrounding the second liquid feeding port, and the exhaust port has a ring shape surrounding the first liquid feeding port.

6. The filter device according to claim 1, wherein the first and the second liquid feeding ports are positioned such that the first and the second liquid feeding ports have the openings to the opposite end portions of the accommodating space in a horizontal direction, respectively, the filter is accommodated in the accommodating space such that the filter is positioned upright with respect to the horizontal direction, the exhaust port is formed in a plurality on an upper portion of the accommodating space such that the plurality of exhaust ports is positioned on sides of the accommodating space separated by the filter, the tubular exhaust joint is extending out and upward with respect to the accommodating space, and the first tubular joint and the tubular exhaust joint are passing around the accommodating space and extending out and upward with respect to the accommodating space.

7. The filter device according to claim 1, wherein the accommodating space of the housing has a first inner surface formed on a side of the first liquid feeding port such that as the first inner surface recedes from the first liquid feeding port, the first inner surface approaches toward the filter, and the accommodating space of the housing has a second inner surface formed on a side of the second liquid feeding port such that as the second inner surface recedes from the second liquid feeding port, the second inner surface approaches toward the filter.

8. The filter device according to claim 1, wherein the filter has a conical shape having a center portion protruding toward one of the first and second liquid feeding ports which is configured to introduce the processing liquid.

9. The filter device according to claim 1, wherein the filter has a conical shape having a center portion protruding toward one of the first and second liquid feeding ports which is configured to discharge the processing liquid.

10. The filter device according to claim 2, wherein the accommodating space of the housing has a first inner surface formed on a side of the first liquid feeding port such that as the first inner surface recedes from the first liquid feeding port, the first inner surface approaches toward the filter, and the accommodating space of the housing has a second inner surface formed on a side of the second liquid feeding port such that as the second inner surface recedes from the second liquid feeding port, the second inner surface approaches toward the filter.

11. The filter device according to claim 2, wherein the filter has a conical shape having a center portion protruding toward one of the first and second liquid feeding ports which is configured to introduce the processing liquid.

12. The filter device according to claim 2, wherein the filter has a conical shape having a center portion protruding toward one of the first and second liquid feeding ports which is configured to discharge the processing liquid.

13. A filter device, comprising:
a housing having an accommodating space; and
a plurality of filter components positioned adjacent to each other in a horizontal direction in the housing,
wherein each of the filter components includes a filter accommodated in the accommodating space of the housing, a first tubular joint connected to a first liquid feeding port of the housing and having an open end configured to be connected to a supply path of a processing liquid for a semiconductor manufacturing process, a second tubular joint connected to a second liquid feeding port of the housing and having an open end configured to be connected to the supply path of the processing liquid, and a tubular exhaust joint connected to an exhaust port of the housing and having an open end configured to be connected to an exhaust path, the first and the second liquid feeding ports are configured to introduce or discharge the processing liquid and positioned such that the first and the second liquid feeding ports have openings to opposite end portions of the accommodating space, respectively, the exhaust port is configured to exhaust gas separated from the processing liquid and positioned such that the exhaust port has an opening to the accommodating space, the filter is accommodated in the accommodating space such that the filter is intersecting a straight line passing through a center of the first liquid feeding port and a center of the second liquid feeding port, the first tubular joint and tubular exhaust joint of each of the filter components are extending out and upward with respect to the accommodating space of the housing, and the second tubular joint of each of the filter components is connected with each other.

14. The filter device according to claim 13, wherein the plurality of filter components comprises two filter components positioned adjacent to each other and forming a pair of filter components.

15. The filter device according to claim 13, wherein the accommodating space of the housing has a first inner surface formed on a side of the first liquid feeding port such that as the first inner surface recedes from the first liquid feeding port, the first inner surface approaches toward the filter, and the accommodating space of the housing has a second inner surface formed on a side of the second liquid feeding port such that as the second inner surface recedes from the second liquid feeding port, the second inner surface approaches toward the filter.

16. The filter device according to claim 13, wherein the filter has a conical shape having a center portion protruding toward one of the first and second liquid feeding ports which is configured to introduce the processing liquid.

17. The filter device according to claim 13, wherein the filter has a conical shape having a center portion protruding toward one of the first and second liquid feeding ports which is configured to discharge the processing liquid.

18. The filter device according to claim 14, wherein the accommodating space of the housing has a first inner surface formed on a side of the first liquid feeding port such that as the first inner surface recedes from the first liquid feeding port, the first inner surface approaches toward the filter, and the accommodating space of the housing has a second inner surface formed on a side of the second liquid feeding port such that as the second inner surface recedes from the second liquid feeding port, the second inner surface approaches toward the filter.

19. The filter device according to claim 14, wherein the filter has a conical shape having a center portion protruding toward one of the first and second liquid feeding ports which is configured to introduce the processing liquid.

20. The filter device according to claim 14, wherein the filter has a conical shape having a center portion protruding toward one of the first and second liquid feeding ports which is configured to discharge the processing liquid.
